(19) United States
(12) Patent Application Publication
(10) Pub. No.: US 2026/0205001 A1
(43) Pub. Date: Jul. 16, 2026

(54) Voltage Converter Device

(71) Applicant: THE SECRETARY OF STATE FOR DEFENCE, Salisbury (GB)

(72) Inventor: Timothy Richard Crocker, Salisbury (GB)

(21) Appl. No.: 19/450,277

(22) Filed: Jan. 15, 2026

(30) Foreign Application Priority Data
Jan. 15, 2025 (GB) 2500513.3
Sep. 17, 2025 (GB) 2515419.6

(51) Int. Cl. H02M 1/00; H02M 1/088; H02M 3/157; H02M 3/158; H03K 17/0412

(52) U.S. Cl. CPC H02M 1/0054; H02M 1/0009; H02M 1/088; H02M 3/157; H02M 3/158; H03K 17/04123

(57) ABSTRACT

In a switched mode voltage converter device a switching node connects first and second transistor components and an inductor, and the device controls a voltage or current difference between the upper terminal and the inductor terminal. At high load conditions, during dead time, the inductor would normally drive current through the first transistor component once it is turned off, thereby tending to drive it towards being in forward bias ahead of the second transistor component turning on. To prevent this, the second transistor component turns on in a current limited mode, permitting enough current through to prevent the transistor component being in forward bias, in order to prevent shoot through when the second transistor component turns fully on. The second transistor component turns on in its current limited mode at or before the point when the first transistor component turns off. This enables the second transistor to control the voltage of the switching node to prevent the first transistor being in forward bias, whilst permitting the switching time to be minimised.

### CROSS-REFERENCE TO RELATED APPLICATIONS

This application is based on and claims priority under 35 USC § 119 from British Patent Application No. 2500513.3, filed on Jan. 15, 2025, and British Patent Application No. 2515419.6, filed on Sep. 17, 2025, the contents of which are incorporated herein by reference.

### TECHNICAL FIELD OF THE INVENTION

The present invention relates to voltage convertors based on transistor bridges, as well as transistors of the body diode type (particularly Silicon MOSFETS and Silicon Carbide MOSFETS), and to voltage convertor modules, and voltage converter equipment.

It is applicable to voltage converter devices, modules and equipment using switched mode, including switching power amplifiers, including especially those that are direct coupled (i.e. input and output share a common ground terminal), and especially when used in synchronous and current mode (i.e. having active semiconductor switches in each current path, and those where the inductor current does not rest at zero in use).

### GENERAL BACKGROUND

Shoot-through is a critical phenomenon that can occur in voltage converter components, particularly in half-bridge and full-bridge configurations, in which a current pulse occurs if both switches are simultaneously conductive. The main solution described in the prior art, for reducing shoot-through in general is a short period of ‘dead time’ where neither transistor is on.

By way of background, with reference to FIG. 1 as a simplified example, a bridged transistor voltage converter has an inductor (L1) alternately connected via either of two transistors (S1, S2) to a high voltage input/output (RH) and a low/ground rail (Common) which may be thought of as being at 0V.

In normal use, the ratio of the duration of these alternating connections to the two transistors (S1, S2) determines the ratio of the voltage between the high voltage input/output (LH) and the inductor end input/output (RH). RH and LH are connected via respective capacitors (not shown) to Common, making this a direct coupled, switched mode voltage converter.

Turning transistor 2 (S2) on connects the left hand input (LH) to the inductor (L1), leading conventional current to flow to the right through the inductor towards RH. The inductor has the effect of causing the current to have momentum, so when S1 is turned on (and S2 off), conventional current is drawn from the ground/common rail, towards RH. Since S1 and S2 are alternated at kHz speeds, the result is that RH is held at a voltage that is lower than LH, and has a proportionally higher current compared to LH. If LH is provided with a source of high voltage power, and R^{H} is the lower voltage output of the device, then this mode of operation is known as voltage ‘down conversion’. If RH is a source of low voltage power, and LH is the higher voltage output of the device, then this is known as voltage ‘up conversion’.

In the prior art, it is not merely conventional, but absolutely essential, that only one of the two transistors (S1, S2) is set to the ‘on’ state at any moment in time. They are turned on alternately at kHz frequencies, via carefully designed timing circuits (not shown) to ensure there is no overlap, since any overlap would cause a low impedance short circuit. The current pulse generated in this situation is known as ‘shoot-through’ and can potentially damage the transistors or other components in the circuit.

It might be imagined that shoot-through can be completely avoided by implementing ‘dead-time’, i.e. closing one transistor a short period of time before opening the other. However, the inventor has identified that at high load this does not prevent ‘shoot-through’, and is not the best solution to mitigating it.

### BACKGROUND TO THE INVENTION

Previously, eliminating shoot-through in half-bridge and full bridge transistor-based configurations in all situations and modes has not been possible, especially with Silicon and Silicon Carbide MOSFETs (Metal-Oxide-Semiconductor Field-Effect Transistors). Manufacturers have made do with eliminating it in most modes and minimising it in others. For example at low load, shoot through can be addressed by introducing a very short dead time in combination with efforts to avoid gate ringing such as controlling the switch to turn on/off gradually, reducing parasitic capacitance in the circuit, and using well-damped drive circuits.

Another known way to partially mitigate shoot-through at low power, which is to add a schottkey diode in parallel with the MOSFET, since these have a faster diode recover time and smaller forward bias voltage, and their presence helps prevent the MOSFET entering full forward bias. Unfortunately, schottkey diodes tend to be low power devices—around 10 or 20 W—and the more powerful ones have less desirable properties in terms of diode recovery time and forward bias voltage, whilst also being expensive and requiring board space. So again, the problem remains unsolved at high loads.

Identifying when shoot through is occurring is extremely difficult, since it is not possible to measure the current within the transistors at high load without affecting the behaviour of the voltage converter.

The inventor has identified that at high load, the conventional forward current through the inductor (see FIGS. 1 and 9) does not pass through zero before the conduction path is switched from one transistor to the other, causing one of the transistors to have reversed polarity and despite being turned off will remain conductive due to activation of its internal diode until the other one is turned on. This is explained via the following two examples:

When the circuit shown in FIG. 1 is used as a down converter at high load, with a power source connected to LH:
Here the conventional current passing to the right through the inductor will increase whilst S2 is on (i.e. conducting), and will decrease—but not to zero—whilst S1 is on.
When S1 gets closed, the conventional current will continue to travel to the right through the inductor (since inductors induce an electrical property analogous to momentum), which reduces the voltage at ‘A’ to the point that S1 experiences reversed polarity.
The intrinsic diode (body diode) will be activated if the reverse polarity exceeds a certain voltage (typically about 1V), in which case S1 will remain conductive until the moment that S2 is turned on. Since the diode takes a finite amount of time to turn off, this causes a finite duration short circuit.
In summary, a momentary short circuit occurs when S2 turns on.

When the circuit shown in FIG. 1 is used as an up converter at high load, with a power source connected to RH:
Here the conventional current passing to the left through the inductor will increase whilst S1 is on (i.e. conducting), and will decrease—but not to zero—whilst S2 is on.
When S2 gets closed, the conventional current will continue to travel to the right through the inductor (since inductors induce an electrical property analogous to momentum), which increases the voltage at ‘A’ to the point that S2 experiences reversed polarity.
The intrinsic diode (body diode) will be activated if the reverse polarity exceeds a certain voltage (typically about 1V), in which case S2 will remain conductive until the moment that S1 is turned on. Since the diode takes a finite amount of time to turn off, this causes a finite duration short circuit.
In summary, a momentary short circuit occurs when S1 turns on.

The phenomenon occurs with bridged transistor based voltage converters using Silicon MOSFETs and Silicon Carbide MOSFETs and any other transistor that has an intrinsic diode (also known as a body diode), especially those where the input and output are connected to a common ground (see FIG. 2). However it does not occur when the device is operating at a sufficiently low load that the current through the inductor alternates in direction.

A great deal of effort has been devoted to minimising switching losses and in particular ‘shoot through’, although in general the emphasis is on shoot-through as a whole rather than the effect the inventor has identified that becomes a problem at high load.

As mentioned, the main solution for reducing shoot-through in general is a short period of ‘dead time’ where neither transistor is on. Another approach that can improve on this is known as ‘adaptive’ gate drive, where not merely the length of ‘dead time’ but the rate of change of voltage applied to the gate of each transistor (either side of the dead time) is controlled. It has been argued that by switching the gates of the two transistors in a slightly slower and controlled fashion (for example using a damping resistor) before and after the dead time, reduces the problem in a manner which is worth the temporarily reduced efficiency. But even with adaptive gate driving circuits, the designer still applies a dead time to avoid a direct low-inductance short circuit with a huge current which would destroy they device or greatly limit its power or voltage rating.

A discussion of dead time and adaptive gate drive is provided in ‘AN-6003 “Shoot-through” in Synchronous Buck Converters’ by Fairchild Semiconductor® which at time of writing is available via: https://www.alldatasheet.com/datasheet-pdf/download/163915/FAIRCHILD/AN-6003.html. This document describes the problem primarily in relation to voltage converters used as, or optimised as, down-converters (Buck converters), whilst the present invention is applicable to both up and down conversion. The document discusses the possibility of eliminating shoot-through, however the inventor considers it unlikely that this is ever achieved for both transistors at high load conditions.

Another discussion of dead time reduction in MOSFETs is found in “Time to kill the dead time” Andrea Gorgerino, Director of Global Field Applications Engineering, EPC available at time of writing at: https://www.powersystemsdesign.com/articles/time-to-kill-the-deadtime/97/19355, which describes how the presence of dead time causes perturbations in the voltage output, which can cause audible noise and reduced efficiency and torque in high torque motor drives. The document describes the need to reduce dead time to nearly zero, and suggests that the solution might be to switch from Silicon MOSFETs to the much more expensive Gallium Nitride Field Effect Transistors, since they offer faster switching speed and are immune to the body diode (intrinsic diode) problem.

The publication concludes “Although not quite able to eliminate it, GaN FETs deliver a strong blow to ever-present deadtime.”

Another discussion of dead time reduction and the problem of the polarity of the MOSFET internal diode is found in “Dead-Time Optimization for Maximum Efficiency” available at time of writing at: https://epc-co.com/epc/Portals/0/epc/documents/papers/Dead-Time % 20Optimization %20for %20Maximum %20Efficiency.pdf.

This white paper from Efficient Power Conversion Corporation, discusses the possibility that addition of a Schottky diode in parallel with the MOSFET could be beneficial, provided that it had a lower activation voltage than the MOSFET's internal body diode, and provided that it has faster recovery time than the MOSFET's internal body diode. However the paper concludes that this would only be advantageous if the Schottky diode was monolithically integrated with the MOSFET (which would be difficult). Implicitly the paper is suggesting that although this prevents the MOSFET diode being activated so that you do not have to wait for it to recover, you do still have to wait for the Shottky diode to recover (which although faster, will still require some finite time-especially so given the need to account for component to component variation), meaning that it is still necessary to implement dead time to avoid ‘shoot through’ (i.e. short-circuit). Again, the paper suggests that the problem is best addressed by switching from Silicon MOSFET to Gallium Nitride. Notice in particular that by attempting to make the diode recover ‘faster’, it is attempting to reduce the period of time during which shoot through occurs, so the technique reduces, rather than prevents shoot through.

US2018294723 describes a down (buck) converter, with upper and lower transistor circuits, each having a large and a small transistor, enabling both to have fully on and partially on modes. The patent suggests to prevent the lower transistor being in forward bias the lower transistor circuit switches from fully on to partially on and then off, and the upper circuit switches from off to partially on and then fully on, such that there is a point in the middle where both are partially on. The small transistors have high resistance due to being small, and so would permit a current that is proportional to the voltage across them when switched on. Whilst this could have benefits, the effect of the two small transistors on the switching node voltage are opposite and would tend to cancel each other out for at least part of the time. The document does not teach how much current is needed or how to enable the right amount of current under different conditions (i.e. different input/output voltages of the buck converter), and the use of small transistors to limit the current would suggest that the correct current could only be achieved for a particular voltage difference between the second and third terminals.

The disclosure and teaching in US2018294723 that the intermediate state of the lower transistor circuit turns off before the upper transistor circuit turns on is important because it shows that even the author of US2018294723 considered it important that the intermediate state is NOT on continuously throughout the pre-energising period i.e. in this regard it conforms with the conventional view that what is known as a period of ‘dead time’ is essential.

In addition, the inventor has identified that by focussing on an intermediate state offered by the transistor that is about to turn on (at the end of the de-energising period) (as opposed to in US2018294723 which does not focus on the transistor that is about to turn on and instead suggests an intermediate state using both transistors which would tend to cancel out each other's effect on the switching node voltage to some degree), this offers improved performance that scales to higher voltage devices better than the approach described in US2018294723.

In a preferred embodiment the device is arranged to operate with the high voltage rail (output terminal in the case of an up converter, input terminal in the case of a down converter) at a voltage of at least 12V (relative to the ground rail) and preferably at a voltage of at least 24V and optionally at a voltage of at least 48V.

In summary, although great effort has been expended to mitigate shoot-through, it has not been eliminated in high load conditions with transistors that have a body diode. Shoot-through not only causes more significant electrical inefficiency and heat-loss and increases the requirement for head dissipation components, but most importantly it can destroy the components, or—more sensibly—it limits the voltage rating and current rating of the device.

Although power and voltage can be boosted by adding more devices or complex stacking arrangements, Silicon MOSFETs devices are currently better suited up to a few kilowatts, at voltages below 100V and certainly below about 350V, with 650V pushing the limits of the technology. So if shoot-through could be prevented, the performance envelope of Silicon MOSFETs would be extended into what has been seen as Silicon Carbide territory, whilst the performance of Silicon Carbide would be extended to support even higher voltages and currents than it currently does. Additionally, by reducing switching losses, high load voltage converters could operate at higher frequencies, providing greater voltage precision and dynamic change, as well as needing smaller inductors, smaller heat sinks, and potentially reducing the size and cost of the devices too.

At present the majority of the world's manufacturing capability for voltage converters happens to be for Silicon MOSFETs, however these devices are less suitable for many important green technologies such as utility-scale solar panels, wind turbines, high torque drives and fast chargers for electric cars, and grid scale inverters (among many other applications).

A solution to prevent shoot-through at high load could enable the output of this existing manufacturing capacity to be leveraged to accelerate proliferation of a wide range of green technologies, and thus significantly boost the green or net-zero ambitions of many countries.

More generally the invention facilitates improved power rating, voltage rating, electrical efficiency, dynamic performance, physical compactness, reduced cost and/or reduced heat dissipation, in body-diode based bridged-transistor based voltage converters, including MOSFET transistors and Silicon Carbide transistors.

### SUMMARY OF THE INVENTION

Accordingly it is an object of the present invention to provide an improved body-diode type transistor-bridge based voltage converter which provides for voltage up-conversion but alleviates the aforementioned problem.

According to a first aspect of the present invention there is provided a voltage converter device comprising:
a circuit element comprising:
   a first transistor component being an intrinsic diode transistor component, connecting a switching node to a first terminal for a first voltage, and
   a second transistor component, connecting the switching node at least to a second terminal for a second voltage;
an inductive component, connecting the switching node to a third terminal for an intermediate voltage; and
a control circuit arranged to cyclically control the intrinsic diode transistor component to be in at least off and on states, and the second transistor component to be in on, off, and intermediate states, in the following order:
   an energising period defined by the second transistor component being on, and intrinsic diode transistor component being not being on, for energising the inductive component,
   a post-energising period defined by neither being on;
   a de-energising period defined by the intrinsic diode transistor component being on, and the second transistor component not being on, for permitting the inductive component to draw or drive current through the intrinsic diode transistor component; and
   a pre-energising period defined by neither being on, with the second transistor component being for at least part of the time in its intermediate state;
wherein the second transistor component is arranged such that, in use, in the intermediate state it supplies or draws current to or from the switching node, and respectively from or to a voltage terminal, such as to pull the voltage of the switching node away from the voltage of the first terminal, in the direction of the voltage of the second terminal;
   characterised in that:
the intermediate state of the second transistor component is activated substantially at or before the end of the de-energising period; and
wherein in the intermediate state, the second transistor component conveys substantially the same or more current to or from the switching node, than that respectively conveyed from or to it by the inductive component.

Activating the intermediate state of the second transistor component whilst the first transistor component is fully on is a marked departure from the prior art which emphasises the need for a non-zero amount of dead time where neither device is on.

By doing this the intermediate state is able to adjust the voltage of the switching node such that the first transistor component isn't (or ceases to be) in forward bias, whilst minimising the time that neither transistor component is fully on, thereby greatly improving electrical performance.

Ensuring the intermediate state is active throughout the pre-energising period helps ensure that the current it supplies to the switching node drives (and sustains) the voltage of that switching node away from the region which would otherwise cause the first transistor component to be in forward bias which could cause it to have an activated internal diode. Any variation in the strength of the intermediate state (E.g. any reduction in the conductivity of the electrical path by which it supplies/draws current) should a avoid any dip that would cause the first transistor to be forward biassed, and this is especially important to avoid at the end of the pre-energising period (which is what US2018294723 describes).

That said, if the intermediate state is provided by activating an electrical pathway from the rail corresponding to the second transistor component, this is to cause a change in switching node voltage towards the voltage of that rail. As such over time during the pre-energising period the voltage difference between the switching node and that voltage rail will decrease, which (if the resistance of the intermediate state is constant) will result in a peak in initial current reducing throughout the pre-energising period to approach a final current. Absent very finely controlled variation in the conductivity of the intermediate state, this may be hard to avoid simply due to the effect of Ohms law. However, the final current still should be near the current drawn/provided by the inductive component. If it is higher than that, this would be a waste of electrical current, and if it is lower than that then this risks pulling the switching node voltage into the voltage range which would cause the first transistor component to become forward biassed.

Therefore, turning the intermediate state entirely off for a long enough period before the end of the pre-energising period as to constitute a dead time of its own and to have an effect comparable to a dead time (i.e. an amount of time chosen to ensure that one transistor is turns substantially to its fully on state only once the other is has turned to its substantially off state in the hope of avoiding shoot through), is outside of the meaning of ‘substantially continuously throughout the pre-energising period’.

Also preferably the first transistor is switched from fully off to fully on at the end of the pre-energising period (in practice transistors go through a smooth transition that is not infinitely fast), substantially in a smooth transition without any pause constituting a maintained intermediate state. Preferably to achieve this, a gate voltage of the (or each) transistor of the first transistor component are adjusted substantially in binary fashion from off to on in a single action (and in general this would be controlled from a control unit, again in binary fashion, so that its control signal switches between the two states, off to on at the end of the pre-energising period). Or put another way, the controller and first transistor component are arranged such that at the end of the pre-energising period the first transistor component turns from fully off to fully on substantially as a binary state transition. This has the advantage that an intermediate state offered by the first transistor component would tend to cancel out or weaken the effect being achieved via the intermediate state offered by the second transistor component to some degree, requiring the latter to involve a larger current or to take longer, both of which would lead to reduction in electrical efficiency.

In general, the de-energising period means the period when the intrinsic diode transistor component is substantially fully on (in a manner which, absent the effect of any intermediate state of the second transistor component). It desirably turns off in a binary fashion at the end of the de-energising period. The intermediate state of the second transistor component desirably turns on whilst the first transistor component is still substantially fully on.

Typically the second transistor component is arranged, and the control circuit is arranged to control it, such that in use, the second transistor component conveys a charge that is substantially the sum of:
the charge drawn or provided by the inductor during that pre-energising period (minus any charge provided or drawn by the first transistor component if, preferably but not necessarily, we are focussing on a period beginning before the end of the pre-energising period rather than strictly talking about the pre-energising period), and
the charge required to charge or discharge capacitances at the switching node to change the switching node voltage before the end of the pre-energising period, from being from outside to inside the range of the voltage of the first terminal and the voltage of the second terminal.

By doing this, the intermediate state is able to adjust the voltage of the switching node such that the first transistor component ceases to be in forward bias, whilst minimising the time that neither transistor component is fully on and avoiding the supply of more current than is needed to achieve the desired effect of preventing shoot through, thereby greatly improving electrical performance.

Typically, and preferably, the intermediate state of the second transistor component is activated before the end of the de-energising period. This is key to helping ensure the first transistor component does enter forward bias, and remain conductive when turned off.

Preferably, substantially throughout the period of from the end of the de-energising period to the end of the pre-energising period, the current conveyed by the second transistor component to the switching node is substantially the current conveyed from the switching node to the inductive component, and substantially throughout the period of from when the intermediate state is activated to the end of the de-energising period the current conveyed by the second transistor component to the switching node substantially exceeds the current conveyed from the switching node to the inductive component. This has the advantage of helping ensure the first transistor component never enters first bias as it starts turning off and also helping ensure that it does not then enter first bias as the handover to the second transistor component is completed. The supply of more current to (or from) the switching node by the second transistor component, than is drawn by (or supplied to) the inductive component, helps prevent the intrinsic diode component being in forward bias (and therefore avoid it being highly conductive, thanks to its intrinsic diode, and the natural delay before that diode turns off) at the time that the second transistor component turns on. This is key to preventing a short circuit, or ‘shoot through’ event when the second transistor component turns on.

Preferably the second of the two components of charge is proximate to the capacitance(s) of the switching node times the voltage of the second terminal minus the voltage of the switching node at the start of the intermediate state period.

Or put differently, preferably the second of the two components of charge is closer to the capacitance(s) of the switching node times the voltage of the second terminal minus the voltage of the switching node at the start of the intermediate state period, than to the capacitance(s) of the switching node times the voltage of the first terminal minus the voltage of the switching node at the start of the intermediate state period. Or put differently, preferably the voltage of the switching node is controlled to change to be proximate to the second terminal.

This has the advantage that not only is the first transistor component prevented from being in forward bias at the end of the pre-energising period, but the switching node is already near or at the voltage it will be when accepting charge from the fully on second transistor component, thus mitigating voltage fluctuations and improving electrical efficiency.

Preferably the intermediate state period consists of a first portion up to and including the end of the deenergising period, and a second portion after the end of the de-energising period, and wherein, during the second portion the charge from the second transistor component conveyed to the switching node is substantially equal to the charge conveyed between the switching node and inductive component. In effect this requires that a pulse of current is supplied during the first portion, and this modifies the voltage of the switching node to prevent, or alleviate, it's tendency that at the end of the de-energising period it will be at a voltage that makes the first transistor component be in forward bias.

Achieving this before or at the end of the de-energising period avoids it being in forward bias as the second transistor component turns on whilst minimising the time delay between the first transistor component turning off and the second transistor component turning fully on, which permits improved performance whilst alleviating or preventing shoot through.

Preferably the intermediate state is active at the beginning substantially throughout the pre-energising period. This is important because if the intermediate state has any pauses these ought to be compensated for by supplying extra current afterwards to prevent the first transistor being in forward bias else some conductivity remains in its internal diode causing shoot through. As such although the intermediate state may have a pulse of extra current near the beginning before reducing to around the level of current drawn by the inductor, it should not have pauses, or else any such pauses should be as minimal as possible. Preferably substantially throughout the period of from the end of the de-energising period to the end of the pre-energising period, the current conveyed by the second transistor component to the switching node is substantially the current conveyed from the switching node to the inductive component, and substantially throughout the period of from when the intermediate state is activated to the end of the de-energising period the current conveyed by the second transistor component to the switching node substantially exceeds the current conveyed from the switching node to the inductive component. This approach is advantageous since it offers a pulse of current prior to first transistor component turning off, helping ensure it will not be forward biassed at that moment, but then offers continued current at a lower level which helps prevent the first transistor becoming forward biassed afterwards.

Preferably the second transistor component is arranged, and the control circuit is arranged to control it, such that in use, during the pre-energising period, the voltage of the switching node is adjusted from a voltage outside of the range of the first terminal voltage to the second terminal voltage, in the direction of the first terminal voltage so as to be in the range of the first terminal voltage to the second terminal voltage, by the end of the de-energising period. This helps ensure the first transistor component will not be forward biassed when it turns off.

Preferably the second transistor component is arranged, and the control circuit is arranged to control it, such that in use, from the activation of the intermediate state of the second transistor component to the end of the pre-energising period, the charge conveyed from the second transistor component to the switching node is substantially the sum of:
a first component of charge, being that conveyed from the switching node to the inductive component, minus any charge conveyed from the first transistor component to the switching node; and
a second component of charge that is in the range of the capacitance(s) of the switching node times the voltage of the first terminal minus the voltage of the switching node at the start of the intermediate state period; and —the capacitance(s) of the switching node times the voltage of the second terminal minus the voltage of the switching node at the start of the intermediate state period.

Typically the charge conveyed from the first transistor component to the switching node would be zero or very small but not necessarily. Either way this approach of providing a charge substantially matching that conveyed to the inductive component, plus an amount of charge corresponding to that required to move the switching node voltage to the range of the first and second terminal voltages, is optimal for ensuring that the switching node voltage is moved into the range of the first and second terminal voltages, without using an unnecessary amount of current. Moving the switching node voltage proximal to the first terminal voltage is desirable prior to turning the first transistor component off, and moving the switching node voltage proximal to the second terminal voltage is desirable prior to the second transistor component turning on. This both helps ensure the first transistor component is not forward biassed (in some cases referred to herein as a reversed polarity) when it turns off and thus will not remain conductive, but also helps minimise voltage fluctuations of the switching node when the second transistor component turns fully on, which improves electrical efficiency.

Preferably the second of the two components of charge is closer to the capacitance(s) of the switching node times the voltage of the second terminal minus the voltage of the switching node at the start of the intermediate state period, than to the capacitance(s) of the switching node times the voltage of the first terminal minus the voltage of the switching node at the start of the intermediate state period. Again, this helps minimise voltage fluctuations of the switching node when the second transistor component turns fully on, which improves electrical efficiency.

Optionally the control circuit is configured to dynamically adjust the dead-time duration based on real-time feedback from the switching node voltage or inductor current. This improves efficiency and robustness across varying loads and temperatures.

Optionally the control circuit is configured to calibrate the gate voltage for the intermediate state based on historical performance data or startup diagnostics (particularly if the main transistor is used via intermediate gate voltage). This has the advantage of accounting for component-to-component variation and aging.

Optionally the voltage converter device (or e.g. method) is arranged to operate with a voltage ratio between first and second terminals that exceeds 1:20. A well designed voltage converter implementation generally avoids a high voltage ratio as this results in lower performance than a two-stage system, however with the present invention improved performance makes higher voltage ratios competitive with two stage conversion systems.

The invention is applicable to any switched mode voltage converter in which the first transistor component is a semiconductor switch comprising an intrinsic diode (or body diode) that continues to conduct for a finite time after the switch becomes reverse biased. i.e. termed an intrinsic diode transistor component. To a very good approximation, this equates to a body-diode MOSFET, such as a Silicon MOSFET or a Silicon Carbide MOSFET.

The second transistor component and control circuit are preferably arranged such that in the intermediate state the second transistor component supplies a current between the voltage terminal (a terminal comprised in the voltage converter which isn't the terminal of the first transistor component), and the switching node, that is substantially independent of the magnitude of the voltage difference therebetween.

In practice, making the current truly independent from the switching node voltage may not be possible, but making the current substantially independent of the switching node voltage is highly desirable, and at least it should not be dominated by the voltage across the transistor (i.e. the switching node voltage, assuming a constant terminal voltage) as would be the case if the transistor were operating in the on state (i.e. where current is proportional to voltage).

Ways to supply appropriate current to meet the requirement, but not more, include dynamically varying the intermediate to suit the conditions based on an operating map, adjusting the intermediate state based on a feedback loop based on earlier cycles, but most preferably controlling that/those transistor(s) of the second transistor component involved in providing the intermediate state, by providing a gate-to-source voltage matching their active (aka saturated) operating region (as opposed to making the operate in the linear (aka triode) region.

The term ‘circuit element’ means either a half bridge or (with the addition of a second inductive component or capacitor) a full bridge, or part of some other bridge arrangement e.g. for three phase output.

The third voltage is an input or output voltage (whilst the second voltage is the correspondingly opposite output or input voltage), and is generally substantially a constant voltage over the period of a cycle, at least in use during the steady state period (i.e. not necessarily at the moment the voltage converter is turned on or of, or connected/disconnected from other equipment)—i.e. any fluctuations over a cycle are small compared to the difference between the first and second terminals. This voltage may intentionally vary over time, e.g. to produce an intentionally varying output voltage, such as an AC input or output or as a varying drive voltage for controlling industrial equipment, but at any point in time the device is attempting to provide a specific voltage. Exceptionally in the case of an up converter, the third voltage can be very slightly higher than the second voltage (due to losses), but as a general rule, the third voltage is intermediate the first and second voltages.

It is possible to use the third terminal, or indeed set up additional rails (terminals) at different voltages-however generally the transistor doing the intermediate state needs to cope with forward bias. The first and second terminals are in general first and second rails, i.e. one out of the first and second terminals (i.e. the lower terminal), is typically a common, or zero notional volt, rail.

This has the effect of helping ensure that when the intrinsic diode component turns off, the voltage at the switching node changes in such a direction that the intrinsic diode ceases to be in forward bias, and accordingly its intrinsic diode turns off, ahead of the point that the second transistor component turns fully on. As such it prevents a short circuit when the second transistor component turns on, without causing a short circuit before the inductive component turns off.

Although there is a loss of efficiency caused by allowing current through to hold the switching node voltage at a level that will prevent forward bias, appropriate design enables this loss of efficiency to be less than the gain in efficiency caused by mitigating or preventing shoot through. Further, the reduction or absence of shoot through reduces the strain on the components, enabling use of higher currents and/or voltages.

Accordingly this approach enables an improved voltage converter to be designed which provides at least one of, if not multiple of: higher maximum current, higher maximum voltage, higher efficiency, higher dynamic performance, lower cost, lower size or lower heat dissipation.

By improving the efficiency, the heat dissipating components can be reduced in size and cost, and by preventing or reducing shoot through higher current and higher voltages can be tolerated, with smaller high frequency damping components. As such the invention makes it possible for a designer to achieve a voltage converter that is an improvement in terms of all six of higher maximum current, higher maximum voltage, higher efficiency, lower cost, smaller size and lower heat production, simultaneously, but of course the designer may choose to prioritise some performance characteristics at the expense of others and is not obliged to improve all of these performance characteristics.

A key difference is that:
In a general prior art voltage converter, each transistor component is switched off ahead of the other turning on i.e. this involves ensuring there is dead time following the on period of each of the transistors. Typically great effort is spent optimising the amount of dead time to the nanosecond. However with the present invention, for at least one of the transistor components (if not both), it switches to a partially on state substantially at or before (or when or before) the other one turns of, and remains in that state up until it turns on, which involves ensuring there is not dead-time following the on period of at least one (if not both) transistors.
Whilst US2018294723 attempts to solve the same problem, it proposes providing the intrinsic diode component to have an intermediate state during the pre-energising period, as well as the energising component to do so, which would tend to cancel each other out in terms of their effect on the switching node. It only proposes turning the energising component to be in an intermediate state significantly after the other one's fully conductive state has ended and also misses a second key point, namely that the intermediate state should allow more current than is passing through the inductor. This, along with it suggesting to leave the intrinsic diode in an intermediate state too, both serve to undermine achieving the effect that the present invention aims to provide-namely that in a buck converter the switching node voltage would rise in magnitude so that the low side transistor diode would deactivate, or in a boost converter the switching node voltage would fall in magnitude so that the high side transistor diode would deactivate. Further, by using small transistors, it proposes an intermediate state that is governed by the resistance of those small components, which means that the current through them will be proportional to the voltage difference across them, which prevents the device being operable at varied input/output voltages.

In general, in the intermediate state the second transistor component needs to be sufficiently conductive that, in the case that the current through the inductive component maintains a consistent direction throughout the de-energising period, this state permits sufficient current to or from the switching node, to prevent the voltage of the switching node driving the diode transistor component fully or partially into forward bias during the pre-energising period, so as to prevent or limit a short circuit through the two transistor components when the second transistor component is switched on.

Although the device can operate with positive voltages at the first and third terminals (relative to the common or ground voltage that the second component terminal acts as), the device can equally operate with negative voltages at the first and third terminals (relative to the second one). In normal (and steady state) use, the third terminal will be at a voltage intermediate the first and third ones (barring that when operating as an up converter, the voltage of the first terminal can be controlled to be as low as that of the second terminal, and—due to electrical losses—slightly lower).

The optimal resistance of the opposed transistor component in its intermediate state will vary widely depending on the power and voltage, the voltage ratio between 1st and 3rd terminals, the type of transistor used, the size of inductive component (a larger inductive component requires a lower resistance), the load (higher load requires lower resistance) so in practice it is necessary to consider whether this will be a fixed resistance, or a variable one, and accordingly choose the requisite resistance that is optimal for the design considerations (E.g. whether efficiency is of primary concern, or load rating etc).

The point is that the resistance in the intermediate state should be sufficient to conduct enough current to prevent the diode transistor component being driven into reverse polarity sufficiently far as to activate its inherent diode, but barring to account for tolerances and component variation, the designer should avoid this current being unnecessarily higher.

Similarly, the duration of the intermediate state, the timing when it is turned on and off, are all to be optimised by experimentation, trial and error, or simulation, taking into account the desired electrical properties of the voltage converter and manufacturing variation expected.

The term ‘inductive component’ covers inductors (used when galvanic isolation of the input and output is not required) ‘coupled inductors’ often referred to more loosely as transformers (used to achieve galvanic isolation usually for safety reasons, albeit usually accepting a small loss in efficiency), and also situations where the load itself provides the required inductance, an example being when a transistor half-bridge is used to supply power to an electrical motor (with the motor windings providing the required inductance) or when the half bridge is used to supply power into a battery management circuit, driving circuit or power supply circuit that resists fast changes in current in a manner analogous to an inductor.

The term ‘short circuit’ should be understood in light of the term of art ‘shoot through’, which is uncontrolled and momentary high current, which is known for stressing the components and limiting their power or voltage rating. A conductivity that prevents a short circuit, one which usefully mitigates or eliminates the shoot-through problem.

In general, the transistor that has an intrinsic diode is a vertical field effect transistor.

In general the transistor that has an intrinsic diode is a unipolar transistor.

In general the transistor components (or indeed transistors) are controlled using Pulse Width Modulation signals from the control circuit.

In general the control circuit comprises gate drivers, adapted to provide amplified control signals for controlling respective gates of the transistors of the voltage converter.

In general, the second transistor component and control circuit are arranged such that in the intermediate state the second transistor component supplies a current between the voltage terminal and the switching node, that is non-proportional to the magnitude of the voltage difference therebetween, such that a fractional change in voltage difference either does not cause a change in current or causes a smaller fraction change in current; wherein in the intermediate state, the second transistor component conveys substantially the same or more charge to or from the switching node, than that respectively conveyed from or to it jointly by the inductive component and intrinsic diode component.

Preferably the second transistor component and control circuit are arranged to provide, in use, the intermediate state by setting the gate-to-source voltage of a transistor of the second transistor component, to be within the region of the transistor in which the drain source current is substantially determined by the gate source voltage (sometimes referred to as a saturation region or active region).

The use of the saturation region allows the intermediate state to be largely, or ideally very much, non-proportional to (ideally close to independent of) the source-to-drain voltage, and as close as possible to providing a constant current irrespective of the voltage of at the switching node. This is key to making the device more suited to operation at a range of working voltages (input and output voltages, or indeed the ratio or difference thereof), whereas if the intermediate state provided a resistive response (i.e. the current being proportional to the voltage difference across the transistor or directly related to the voltage at the switching node), then it would not provide a substantially constant current throughout the pre-energising period. In practice, making the current truly independent from the switching node voltage may not be possible, but making the current substantially independent of the switching node voltage is highly desirable, and at least it should not be dominated by the voltage across the transistor (i.e. the switching node voltage, assuming a constant terminal voltage) as would be the case if the transistor were operating in the on state (i.e. where current is proportional to voltage). The saturation (or active) operating region of the transistor where current is primarily a function of gate-source voltage, is to be contrasted with the linear (or triode) operating of the transistor in which current is primarily a function of drain-source voltage.

The transistor is preferably a MOSFET. Taking a MOSFET as an example, the saturation region (active region) occurs when V_{DS}>V_{GS}−V_{TH}, where V_{GS} is the gate-to-source voltage and V_{TH} is the threshold voltage. The channel becomes “pinched off,” and further increases in V_{DS} have little effect on the drain current (ID). The drain current is primarily controlled by V_{GS}, making it largely constant, or preferably nearly constant, regardless of changes in V_{DS}.

With an n-channel upper transistor/mosfet (which better suits high currents than a p-channel one), the source is connected to the switching node, so the gate voltage should be controlled with respect to the source to node voltage, i.e. control the gate to be at a predetermined voltage with respect to the switching node. By contrast with a p-channel upper transistor/mosfet, the gate should be controlled to be at a predetermined voltage with respect to the upper terminal (rail).

Typically, the means to permit the second transistor component to be held in an intermediate state, comprises a control circuit arranged to cyclically supply alternating on and off gate voltages to both transistor components during the energising and de-energising periods, and to supply an intermediate gate voltage to at least one transistor of the second transistor component during the pre-energising period to hold the second transistor component in the intermediate state.

This has the advantage that by modifying the control circuit of a conventional voltage converter, it becomes possible to improve its performance. Typically this would involve providing a control voltage to control the gate of a transistor of the opposed transistor component, and typically the gate voltage corresponding to the intermediate state, would be a voltage intermediate relevant voltages used for the on and off states. The difficulty with this embodiment is that it would take great care to choose the right intermediate gate voltage, noting that this might need to take into account the current or load on the device, and perhaps on component-to-component variation—i.e. may require calibrating.

An alternative way to control the intermediate state such that the fractional change in voltage results in a smaller fractional change in current, would be to measure the voltage difference between the switching node and the terminal, and control the conductivity of the intermediate state to be higher at a low voltage difference than a high voltage difference. This kind of feedback loop however would need to be very fast, which is a challenge at voltage converter switching speeds.

Preferably the intermediate state of the second transistor component is activated before the end of the de-energising period. By ‘before’ it is generally meant before but proximal in time to.

By ‘activated’ it is generally meant to change from a state in which it substantially is not conducting, to a state where it conducts in a current limited mode, where its resistance is selected to permit a controlled amount of current but not so much as would be considered a short circuit. If further clarity is required, on and off generally refer to a state operating to maximise or minimise conduction, as is known in the art of switched mode voltage converters, whereas the current limited mode permits an amount of current suited to adjusting the switching node voltage so as to limit or prevent the activation of the intrinsic diode of the first transistor component, but not so much as to cause a short circuit when the second transistor component turns to it is fully on state. The terms off and on generally can be understood to mean the fully on and fully off states. Where there is a reference to operation of the first and/or second transistor components in relation to a particular period such as the de-energising period or pre-energising period, the control circuit generally controls the first and second transistor components to operate in this fashion cyclically and repeatedly, and typically in substantially all cycles at least during conditions of high load, or depending on an operating map.

Preferably the control circuit is adapted to control the second transistor component to be substantially fully off from a time proximal to the beginning of the de-energising period until being activated at a time proximal to the end of the de-energising period. As such where the second transistor component is activated before the end of the de-energising period this generally should nonetheless be proximal in time to the end of the de-energising period. This is so that the effect of changing the switching node around (or desirably before) the end of the de-energising period can be achieved, but minimising the amount of current used to achieve this. If the intermediate state were activated in the middle of the de-energising period this could have a very deleterious effect of wasting large amounts of electrical energy. In practice the timing of the activation of the intermediate state, and the handover separation time (the delay between turning the first transistor component off to turning the second transistor component fully on) are chosen to maximise a performance function required by a user, which may one or more, or a combination of, maximising the safe operating voltage, maximising the safe operating current, maximising the electrical efficiency, maximising the output current smoothness, and minimising the size of required passive components (inductive component and any dampers required to provide an adequately smooth current and meet relevant emissions requirements). This means that in practice the intermediate state will be activated as early as necessary, and no earlier than necessary to adjust the switching node voltage to prevent or limit the first transistor component being in forward bias when the second transistor component turns fully on.

More generally these parameters (particularly the timing of the intermediate state being activated and handover separation time, and optionally the resistance of the intermediate state) would be varied according to an operating map (any of input voltage, output voltage, current and temperature, but especially based on current), and would typically be optimised through testing by prediction/simulation prior to manufacture. The operating map may also be optimised according to individual component-to-component variation, and/or based on a feedback loop based on monitoring of in-use performance.

In one embodiment the control circuit of the voltage converter device is provided with a current sensor through the voltage converter device, or adapted to receive data on current into/out of the voltage current device, and employs the intermediate state only in the case of current exceeding a threshold current. This has the advantage of optimising the performance of the device at high load conditions and at low load conditions. The threshold preferably corresponds substantially to the minimum current at which the first transistor component would (without use of the intermediate state being employed) be in forward bias upon turning off at the end of the de-energising period. Alternatively/additionally the duration of the intermediate state being employed is varied according to a positive function of current. In the case that the current is below the threshold value and the intermediate is not employed, the second transistor component switches from fully off to fully on, at the start of the energising period.

Given that the duration of the pre-energising period is generally as short as possible given the constraints of component-component variation in response times, this is important for helping ensure that the intermediate state is in place before the first transistor component turns off, which helps ensure that the first transistor will avoid being in forward bias at the moment when the second transistor turns on. In general, the intermediate state will be on substantially throughout the pre-energising period, and preferably is on constantly throughout the pre-energising period. This similarly is important for ensuring that the first transistor will avoid being in forward bias at the moment when the second transistor turns on.

As an alternative the intermediate state of the second transistor component is activated substantially at the end of the de-energising period. This has been identified as still offering some and potentially much of the benefit described in relation to activating it before the end of the de-energising period, and is likely to offer a lesser but still beneficial benefit especially.

If the intermediate state of the second transistor component is activated at exactly the end of the de-energising period (defined as the moment when the first transistor turns off) then the switching node voltage will be such as to drive the first transistor into forward bias albeit perhaps only to a small extent. The second transistor component then has to supply current to drive the switching node voltage out of the region that is activating the intrinsic diode, and be active for long enough for the first transistor to cease being in forward bias. If this is done incompletely then shoot through is not fully prevented, and even if it is done completely, this would require a longer than otherwise necessary delay before the second transistor turns on, which detracts from the efficiency and current delivered by the device.

The intermediate state of the second transistor component should not be merely activated only after the end of the de-energising period and terminated before the end of the pre-energising period, because then the switching node voltage will be such as to drive the first transistor into forward bias causing its intrinsic diode to be activated potentially to a large or complete degree. The second transistor component would then have to supply current to drive the switching node voltage out of the region that is causing forward bias, and be active for considerably longer in order that the first transistor could cease being in forward bias. If this were to be done incompletely then shoot through is not fully prevented, and even if it is done completely this would require a substantially longer than otherwise necessary delay before the second transistor turns on, which detracts from the efficiency and current delivered by the device.

Therefore the benefit is best obtained by ensuring that the intermediate state of the second transistor is activated before the end of the de-energising period, but some benefit may still be obtained by arranging the intermediate state of the second transistor to be activated either exactly at or even substantially at the end of the de-energising period.

When discussing events which occur so rapidly, the miniscule amount of time required for the transistor (E.g. MOSFET) to turn on (often in the range 10 ns to 100 ns) may become significant enough to warrant attention. It is therefore helpful to be clear that the second transistor is considered to be ‘activated’ at the moment that it has turned on (as opposed to the moment a gate voltage is applied to its input to begin the process of turning it on). If greater precision is beneficial, this moment should be defined as the time at which the drain current of that transistor achieves 90% of its final value (also conventionally known as the end of the rise time).

Preferably the intermediate state is configured such that, in use, from the intermediate state being activated at or before the beginning of the pre-energising period to the end of the pre-energising period, the sum of the charge conveyed by the second transistor component between the switching node and the terminal of the second transistor component and/or third terminal, minus any charge conveyed between the switching node and the terminal of the intrinsic diode transistor component, exceeds the charge conveyed by the inductive component between the switching node and the third terminal, by at least a factor of 1.5.

Whilst providing the current to the switching node than taken by the inductive component (or vice versa) should be greater by a factor of greater than 1.0, a factor of 1.5 or indeed 2.0 is preferable as this charges the capacitance of the switching node ahead of the point when the second transistor component turns substantially fully. Exceeding a factor of 1.0 allows us to eliminate shoot-through and associated current spike, but going beyond this to a factor of 1.5, 2.0 or 3.0 or even 5.0, has the further benefit of reducing a different source of current spike, namely the current that charges the capacitance of the switching node. In doing so, this reduces fluctuations which both reduce efficiency and need to be damped, and in turn reduces the damping requirement, and required size and cost of associated damping components.

Preferably the intermediate state is configured such that, in use during the pre-energising period, it adjusts the voltage of the switching node to be proximal to the second voltage, by the end of the pre-energising period.

This is similar to saying that the current supplied more significantly exceeds the current through the inductive component but clarifies that enough current or charge is supplied to account for the capacitance of the switching node (which is always present even if there is no capacitor component there). Moving the voltage of the switching node to become close to that of the second terminal has the advantage that when the second transistor component turns fully on, this results in less of a high frequency current/oscillation, which in turn requires less snubbing/damping, and accordingly improves the efficiency of the device, and potentially reduces the cost and size too. In an ideal world the switching node voltage approaches or equals that of the second terminal at the moment that the second transistor component turns on, but due to manufacturing variations and extremely tight timing tolerances this may be impractical to achieve, especially so across the voltage range, voltage ratio range, and current range of the device.

Preferably the control circuit is arranged to measure the voltage at the switching node, or the current through the inductor, during one or more previous cycles, and to supply any of a predetermined range of gate voltages for holding the energised transistor component in the intermediate state, during the pre-energising period in accordance with an operating map.

The operating map identifies the optimum parameters for any given operating state, according to one or more operating variables (e.g. voltage, current, temperature). This has the advantage that the performance of the voltage converter can be improved across the voltage, load and temperature operating envelope. Unless the operating map is determined individually for each voltage converter (which is more onerous), the operating map should be determined through experimentation, taking into account the identified level of component-to-component variation and the designer's desired safety margin.

Preferably the control circuit is arranged to measure the voltage at the switching node, and to adjust a gate voltage for holding the energised transistor component in the intermediate state during the pre-energising period, based on a variation of the gate voltage from a predetermined target voltage, during the one or more previous cycles.

This has the advantage that the performance of the voltage converter can be improved across the voltage, load and temperature operating envelope, in a manner that is more tolerant of manufacturing variations of the transistors. In a down converter, all that is necessary is to target the switching node voltage being higher than the second terminal by at least the low side transistor forward voltage bias, and if in recent cycles it wasn't high enough, increasing the conductivity of the intermediate state and vice versa. In a boost converter you would target the switching node voltage being lower than the first terminal by at least the high side transistor forward voltage bias.

Preferably the means to permit the second transistor component to be held in an intermediate state, comprises an electrical circuit comprised in the second transistor component, comprising at least two transistors with associated electrical paths and resistances thereof, at least one being connected to the terminal associated with the second transistor component, and the other being connected to either that same terminal or the third terminal, the at least two transistors being arranged such that three predetermined combinations of their on and off states, respectively provide the off state, intermediate state, and on state, of the second transistor component, for being cyclically held in those states by a control circuit.

This has the advantage that a control circuit need only supply binary gate control voltages, or at least may require less refined control of those voltages, and only the timing needs to be accurate. The disadvantage is that it requires an additional control signal from the control circuitry, and a redesign of (and additional complexity in) the voltage converter itself.

It should be noted that despite the addition of a further transistor to provide the intermediate state, this does not prevent it being useful to vary the gate voltages to tailor that intermediate state. The problem with using only one transistor is that the gate voltage needs to be controlled very carefully, to the extent that manufacturing variations in the transistors may need to be taken into account (or e.g. a feedback loop used to optimise the gate voltage). By adding a second transistor and tailored to provide that lower conduction state (E.g. by providing it with a resistor), this makes it less sensitive to manufacturing variations, making it easier to tailor a voltage to adjust the intermediate state. This can be useful for example if the properties of the intermediate state should vary across the current/voltage operating envelope, enabling a more optimal performance than if the intermediate state provides a single fixed conductivity.

Optionally, in the electrical circuit one transistor thereof is connected to the terminal associated with the second transistor component, and another transistor thereof is connected to the third terminal.

As an alternative to both transistors being coupled to the same terminal, one optionally is coupled instead to the third terminal (outboard of the inductive component), to provide a different source of current to drive to/from the switching node. If the voltage at the third terminal is low compared to the second terminal, this could be more electrically efficient although it may produce more high frequency output at the third terminal which may require more damping to prevent. In this embodiment the transistor coupled across the inductive component should be chosen to avoid it entering forward bias at the end of the pre-energising period, and this component may advantageously be a bidirectional MOSFET switch, to ensure full control over whether the switch is open or closed.

Note that in the case of a galvanically isolating inductive component (a coupled inductor), the transistor should be connected to the output of the inductive component that is electrically coupled through the inductive component to the switching node (as opposed to being connected to the otherwise galvanically isolated part of the circuit, as that would serve to undermine the electrical isolation of the two ends of the device).

Typically, in the electrical circuit, both of the transistors are connected to the terminal associated with the second transistor component.

This means that in a down converter, where the low transistor is at risk of entering forward bias, the high transistor component has two transistors coupled to the high voltage rail, enabling at least two conduction states, one being ‘on’, and the other being the intermediate state. By contrast in a boost converter, it is the high transistor that is at risk of entering forward bias, so the low transistor component has two transistors coupled to the low (or ground) rail.

Optionally, the at least two transistors with associated electrical paths and resistances, are arranged in series.

An example of this is shown in FIG. 13. Q2 is the main transistor, and Q3 is arranged to turn off to leave a predetermined resistance available via a side channel. One advantage of this is that the second transistor can be a low voltage rated one, which makes it easy to ensure that transistor provides high conductance when switched on.

Alternatively, the at least two transistors with associated electrical paths and resistances, are arranged in parallel.

An example of this is shown in FIG. 15. Whilst both transistors need to be rated for nearly the same voltage, this has the advantage that it provides for very low ‘on’ state resistance. Additionally it offers the benefit that they can be identical, requiring fewer different components.

In general a primary transistor (or primary group) is arranged to convey the majority of the current in the fully on state. In the case of a parallel circuit topology, the secondary transistor (or secondary group) provides a higher resistance path for the intermediate state (E.g. in combination with a series resistor), and in the case of a series circuit topology the secondary transistor is off to direct current through a resistor arranged in parallel with it. In both cases there is an advantage to the primary transistor/group and secondary transistor/group being of the same base semiconductor material, as they will be subject to the same maximum voltage difference, so to provide a cost-effective solution suiting lower voltage applications (e.g. <800 v) they advantageously both comprise Si MOSFET(s), or suiting higher voltage applications (e.g. >600 v) they advantageously both comprise SiC MOSFET(s). That said, the present invention permits Si MOSFETS to operate more easily at higher voltages so advantageously the voltage converter is adapted to operated at, or is operated with, a voltage of 600-1000 v (the voltage between the first and second terminals in use).

Due to the improved combination of electrical efficiency, current capacity, reduced heat dissipation requirement and heat-sink, and increased switching speed, permitting smaller passive components (inductor and snubbers), a greater improvement is potentially achievable in power density, which for Si MOSFET based switched mode voltage converters is currently around 5-9 W/cm³ for typical devices and 10-15 W/cm³ for high end devices. Preferably the first and second transistor components comprise Si MOSFETs and the voltage converter device has a power density of 10-20 W/cm³, and more preferably a power density of 16-30 W/cm³ and most preferably 20-40 W/cm³. These figures are for the core voltage converter only (including transistors and drivers, circuit board, inductive component, excluding filters, heatsinks/fans, control circuitry, enclosures and connectors). If filters, control circuitry, and input/output capacitors are included then 3-10 W/cm³ is typical, and the voltage converter device preferably has a power density of 7-15 W/cm³ preferably 11-20 W/cm³ and most preferably 15-30 Wcm³.

Optionally the Voltage converter device is arranged to operate as a down converter, wherein in operation as a down converter, the first terminal has a low voltage, and the second terminal has a high voltage.

Optionally the Voltage converter device is arranged to operate as an up converter, wherein in operation as an up converter, the first terminal has a high voltage, and the second terminal has a low voltage.

Preferably the Voltage converter device is arranged to operate as a down converter, wherein in operation as a down converter, the first terminal has a low voltage, and the second terminal has a high voltage;
wherein the second transistor component is a second intrinsic diode transistor component operable to be in on, off and intermediate states, and the voltage converter is further arranged to operate as an up converter, and wherein in use as an up converter the control circuit is arranged to cyclically control the first and second transistor components, through the following states in the following order:
   an energising period defined by the first transistor component being on, and second intrinsic diode transistor component being not being on, for energising the inductive component,
   a post-energising period defined by neither being on;
   a de-energising period defined by the second intrinsic diode transistor component being on, and the first transistor component not being on, for permitting the inductive component to draw or drive current through the second intrinsic diode transistor component; and
   a pre-energising period defined by neither being on, with the first transistor component being for at least part of the time in its intermediate state;
wherein the first transistor component is arranged such that, in use, in the intermediate state it supplies or draws current to or from the switching node, and respectively from or to a terminal comprised in the voltage converter, such as to pull the voltage of the switching node away from the voltage of the second terminal, in the direction of the voltage of the first terminal;
wherein the intermediate state of the first transistor component is activated before the end of the energising period; and
wherein in the intermediate state, the first transistor component conveys substantially the same or more current to or from the switching node, than that respectively conveyed from or to it by the inductive component.

Note that this enables the device to operate as a down converter, and as an up converter as required (albeit not simultaneously), which offers greater flexibility to differing electrical demands and requirements.

In the case that both the first and second transistor components are operable in respective intermediate modes (irrespective of whether the device can operate as an up converter, a down converter, or both), it is preferred that during a switch from one being fully on to the other being fully one, substantially only one of the transistor components operates in its intermediate mode, or if both do then the event is dominated by one of the transistor components operating in its intermediate mode and any operation by the other transistor component in its intermediate mode should be comparatively minor. The reason to substantially avoid both of them entering intermediate mode is that the effects of those intermediate modes will tend to cancel each other out. The transistor component that isn't at risk of entering forward bias should be in its intermediate mode during the transition period, and any use of intermediate mode of the other one should be minimised or avoided.

Optionally the second terminal provides a ground or common voltage rail that is capacitively coupled to the first terminal, and capacitively coupled to the third terminal, such that the three terminals share a common or ground rail.

This situation provides a direct coupled voltage converter, which is the arrangement where the shoot-through effect is most likely to result from switching at high load. An alternative is where the third terminal is provided with a coupled inductor (often called a transformer). This has the advantage of higher efficiency, but less suitable for domestic mains equipment as the output is not galvanically isolated.

Optionally the Voltage converter device is a galvanically isolated voltage convertor in which the inductive component is a coupled inductor connected to the third terminal for an intermediate voltage.

This has the advantage of higher safety, at a cost of a small efficiency loss.

Optionally the control circuit is adapted to detect the load on the voltage converter, and to operate in at least two modes depending on a detected load, including a high load mode where the control circuits controls the second transistor component to be in its intermediate state during the pre-energising period, and a low load mode where the control circuit controls the second transistor component to be off during the pre-energising period.

This has the advantage of maximising the performance of the voltage converter, without causing loss of efficiency at low load conditions.

The first mode would be used in a high load situation (i.e. the voltage converted delivering high current (or power or voltage) relative to its current or (or power or voltage) rating), and the second mode corresponds to the conventional approach, which would be used in a comparatively low load situation. This approach of selecting between two modes has the advantage that efficiency (and/or other performance characteristics) can be optimised both at high load and at low load.

Each voltage converter design will have different characteristics, which can be mapped via testing or modelling, giving rise to two operating regimes, one in which conventional operation is preferable (simply turning off before the other turns on) generally corresponding to relatively low load conditions, and the other in which a ‘shoot-through’ avoidance mode is preferable (turning one from on, to an intermittent or ‘low conductance’ mode, prior to turning the other one on).

The circuit for controllably determining whether the first and second transistor components are to operate in the first or second mode, could be integrated into a control circuit, or at the integrated chip level, or could be a separate circuit. Either way, this either involve a component sensing the overall load on the converter (e.g. the time-averaged current through the inductive component or the voltage converter) or it may involve detecting that the current through the inductive component is alternating (which could be done either directly, or by measuring its magnetic field), or measuring the degree to which the inductive component reverses current direction. Typically this circuit is a digital timing controller, but could in principle be an analogue circuit.

The designer might decide that in the middle ground (e.g. medium load situations) it is not so critical which mode the device operates in, and as such may implement a component to measure the current through the voltage converter, and apply the second mode above a threshold current. Alternatively, the designer may wish to test the efficiency of the voltage converter in both modes at a variety of currents or a variety of currents and voltages, to map which mode is preferable across the (se) variable(s) (or alternatively test for heat generation or other desired measurement criteria, or simply could assess this via computer simulations), and then implement control circuitry to measure the current (or the voltage and current) through/across the voltage converter, and to drive the voltage converter to operate in the most preferable mode given the measured current (or the measured voltage and current).

Typically, the (or each) diode transistor component comprises a Silicon MOSFET or a Silicon Carbide MOSFET.

This corresponds to the main, albeit not all, classes of transistor for which the invention is applicable.

Optionally the (or each) diode transistor component comprises a Silicon MOSFET.

With Silicon MOSFETs the advantage is particularly acute. By eliminating this most intractable form of shoot through that occurs at high load, Silicon MOSFETs, previously thought of as low voltage, low power, devices, can now be driven at much higher power and/or higher voltages, or optimised for greater efficiency or lower heat dissipation, or to have smaller heat sinks and smaller inductive components, and thus be more affordable to manufacture. But enabling MOSFETs to operate at higher voltages and powers makes the suitable for a wider range of equipment, notably a variety of green technologies, such as solar and wind farms, and electric cars and car chargers.

Optionally the (or each) diode transistor component comprises a Silicon Carbide MOSFET.

Silicon Carbide (SiC) MOSFETs are viewed as suited to higher performance applications, and to higher voltages and higher currents compared to Silicon ones. By reducing switching losses, the performance of SiC is improved, such that it could achieve higher powers or higher voltages, or lower losses than currently achievable.

Preferably the control circuit is arranged to activate the intermediate state of the second transistor component before the end of the de-energising period.

Turning the second transistor component to its intermediate state substantially at or before (and preferably before) the fully on state of the intrinsic diode transistor component is turned off, is key to quickly driving the switching node to the required voltage (i.e. a voltage that does not place the intrinsic diode transistor component in forward bias) ahead of the second transistor component turning (fully) on. An alternative approach, such as switching the intrinsic diode transistor component to an intermediate state, ahead of switching the second transistor component may provide for smoother handover, not only detracts from the need to complete the pre-energising period as quickly as possible, but also severely detracts from the desired effect on the voltage at the switching node.

According to a second aspect of the invention, there is provided a method of controlling the voltage converter device, comprising the step of controlling the intrinsic diode transistor component and second transistor component to cycle repeatedly though the states described therein;
wherein the method comprises controlling the second transistor component to provide in its intermediate state, a current between the aforementioned terminal comprised in the voltage converter and the switching node, that is non-proportional to the magnitude of the voltage difference therebetween, such that a fractional change in voltage difference results in a smaller fraction change in current, and;
wherein the method comprises controlling the second transistor component such that in the intermediate state, the second transistor component conveys more charge to or from the switching node, than that respectively conveyed from or to it jointly by the inductive component and intrinsic diode component.

According to a third aspect there is provided a control circuit is adapted to control the first and second transistor components of the voltage converter device of the first aspect, in accordance with the method of the second aspect.

Preferably the control circuit is arranged to activate the intermediate state of the second transistor component before the end of the de-energising period.

A control circuit may be sold separately from the voltage converter as a standalone product. Normally the control circuit also includes gate drivers to amplify the control signals to control the gates of the transistors of the voltage converter.

Preferably the control circuit comprises a gate driver for driving the intrinsic transistor component, and at least two gate drivers for respectively driving the at least two transistors of the second transistor component.

Preferably the control circuit comprises a first gate driver for driving the intrinsic transistor component, and a second gate driver arranged to provide at least three voltages, respectively for controlling the second transistor component to be off, in its intermediate state, or on.

According to a fourth aspect, there is provided a method of designing a voltage converter, comprising the steps of:
selecting components and arrangement thereof to provide a voltage converter as set out in the first aspect;
selecting at least one current or voltage operating region, and an electrical performance criterion;
selecting a plurality of options for the electrical resistance of the aforementioned intermediate state of the second transistor component;
evaluating which of the options provides for the highest performance in relation to the performance criterion and operating envelope, and
selecting a circuit configuration or gate voltage for the second transistor component, to achieve the electrical resistance identified as providing the highest performance.

The electrical performance criterion may by a formula, and may be based on at least one of electrical efficiency (which includes minimising head loss), maximum operating current, and maximum operating voltage. Having selected the criterion which matches the design requirement, the electrical resistance of the intermediate state can be chosen to suit that design requirement.

Especially in the case that a gate voltage is selected so as to provide the desired resistance, this should either be done taking into account component tolerances, or else needs to be optimised for each device individually so as to account for component-to-component variation (primarily the variation in the transistor's response to an intermediate gate voltage).

Preferably in the method:
the step of selecting at least one current or voltage operating region, and an electrical performance criterion, comprises selecting multiple current or voltage operating regions; and
the step of selecting a circuit configuration or gate voltage for the second transistor component, to achieve the electrical resistance identified as providing the highest performance, an operating map is produced, for the control circuit to use to control the voltage converter depending on the voltage or current state of the voltage converter.

In this manner a voltage converter can be designed, so as to have improved electrical performance across a range of operating conditions.

According to another aspect, there is provided a voltage converter device comprising:
a circuit element comprising:
   a first transistor component being an intrinsic diode transistor component, connecting a switching node to a first terminal for a first voltage, and
   a second transistor component, connecting the switching node at least to a second terminal for a second voltage;
an inductive component, connecting the switching node to a third terminal for an intermediate voltage; and
a control circuit arranged to cyclically control the intrinsic diode transistor component to be in at least off and on states, and the second transistor component to be in on, off, and intermediate states, in the following order:
   an energising period defined by the second transistor component being on, and intrinsic diode transistor component being not being on, for energising the inductive component;
   a post-energising period defined by neither being on;
   a de-energising period defined by the intrinsic diode transistor component being on, and the second transistor component not being on, for permitting the inductive component to draw or drive current through the intrinsic diode transistor component; and
   a pre-energising period defined by neither being on, with the second transistor component being for at least part of the time in its intermediate state;
      characterised in that:
the intermediate state is configured such that, in use during the pre-energising period, it adjusts the voltage of the switching node to be proximal to the second voltage, by the end of the pre-energising period.

This has the advantage that not only does it prevent the intrinsic diode transistor component being in forward bias, but goes further than necessary, preparing the capacitance of the switching node to be closer to that which it would then be driven to by the second transistor component, thereby reducing high frequency fluctuations and resulting efficiency losses.

This aspect may be beneficially combined with any or all features described in relation to other aspects.

According to another aspect there is provided a voltage converter device comprising:
a circuit element comprising:
   a first transistor component being an intrinsic diode transistor component, connecting a switching node to a first terminal for a first voltage, and
   a second transistor component, connecting the switching node at least to a second terminal for a second voltage;
an inductive component, connecting the switching node to a third terminal for an intermediate voltage; and
a control circuit arranged to cyclically control the intrinsic diode transistor component to be in at least off and on states, and the second transistor component to be in on, off, and intermediate states, in the following order:
   an energising period defined by the second transistor component being on, and intrinsic diode transistor component being not being on, for energising the inductive component,
   a post-energising period defined by neither being on;
   a de-energising period defined by the intrinsic diode transistor component being on, and the second transistor component not being on, for permitting the inductive component to draw or drive current through the intrinsic diode transistor component; and
   a pre-energising period defined by neither being on, with the second transistor component being for at least part of the time in its intermediate state;
wherein the second transistor component is arranged such that, in use, in the intermediate state it supplies or draws current to or from the switching node, and respectively from or to a terminal comprised in the voltage converter, such as to pull the voltage of the switching node away from the voltage of the first terminal, in the direction of the voltage of the second terminal;
   characterised in that:
wherein in the intermediate state, the second transistor component conveys substantially the same or more charge to or from the switching node, than that respectively conveyed from or to it jointly by the inductive component and intrinsic diode component.

This has the effect of drawing the switching node voltage into the region that helps ensure the relevant transistor component will substantially not be in forward bias, thereby eliminating shoot through. For the avoidance of doubt, the intrinsic diode normally does not convey current at this time, so usually the only requirement is to provide substantially the same or more (and preferably the same or more, and indeed preferably more) charge than conveyed by the inductive component (the inductor or coupled inductor).

Any feature in one aspect of the invention may be applied to any other aspects of the invention, in any appropriate combination. In particular device aspects may be applied to method or use aspects and vice versa. The invention extends to a device, method or use substantially as herein described, with reference to the accompanying drawings.

In all aspects, the invention may comprise, consist essentially of, or consist of any feature or combination of features.

### BRIEF DESCRIPTION OF THE DRAWINGS

The invention will now be described, purely by way of example, with reference to the accompanying drawings, in which;

FIG. 1 is a circuit diagram of a voltage converter;

FIG. 2 is a circuit diagram of a voltage converter, reversed in layout and with additional detail;

FIG. 3 is a circuit diagram of a voltage converter, indicating the presence of the intrinsic diode within each transistor;

FIG. 4 is a circuit diagram of a voltage converter, reversed in layout;

FIG. 5 is a circuit diagram of a voltage converter;

FIG. 6 is a diagram showing the status of transistors S1 and S2, the voltage at the switching node, and the current through the inductor under different conditions;

FIG. 7 is a circuit diagram of a transistor;

FIG. 8 is a diagram illustrating the on-region characteristics of a typical transistor;

FIG. 9 is a diagram showing the status of transistors S1 and S2, the voltage at the switching node, and the current through the inductor under different conditions, the voltage change that causes the transistor to be in forward bias, and the resulting current spike;

FIG. 10 is a diagram showing the status of transistors S1 and S2, the voltage at the switching node, and the current through the inductor under different conditions (traces 10-14) and the same is shown (traces 15-18) when used with the present invention (intermediate state, grey box, in trace 15);

FIG. 11 is a circuit diagram of voltage converter according to an embodiment of the invention:

FIG. 12 is a diagram showing the gate voltages, status of transistors S1 and S2, and the switching node voltage and inductor current, according to an embodiment of the invention:

FIG. 13 is a circuit diagram of a voltage converter according to an embodiment of the invention;

FIG. 14 is a diagram showing the gate voltages, status of transistors S1 and S2, switching node voltage, and inductor current according to an embodiment of the invention;

FIG. 15 is a circuit diagram of a voltage converter according to an embodiment of the invention;

FIG. 16 is a diagram showing the gate voltages, status of transistors S1 and S2, and the switching node voltage and inductor current, according to an embodiment of the invention:

FIG. 17 is a circuit diagram of a voltage converter according to an embodiment of the invention;

FIG. 18 is a circuit diagram of a voltage converter according to an embodiment of the invention;

FIG. 19 is a circuit diagram of a voltage converter according to an embodiment of the invention;

FIG. 20 is a diagram showing point ‘b’ from timing diagrams of FIG. 9 onwards in an expanded scale.

FIG. 21 is a circuit diagram of a voltage converter according to an embodiment of the invention.

### DETAILED DESCRIPTION

This invention will be discussed in relation to the problem of using MOSFETs (particularly Silicon MOSFETS) that are configured in a ‘half-bridge’ which can suffer large ‘shoot-through’ current spikes in certain switching modes which result from the Intrinsic Diode Reverse Recovery characteristics; essentially this diode does not switch off quickly or cleanly on being forward biased. It will apply to other semiconductor families such as Silicon Carbide (SIC) MOSFETs which have the same issue (but to a lesser degree) and also in other switched converter topologies, including those which are not ‘direct coupled’ (ie those with input and output galvanically isolated). It will also apply in applications which would not be considered as power converters such as switching power amplifiers (class E amplifiers).

Because Synchronous MOSFET circuits are intrinsically bi-directional in terms of current flow, use of ‘Input’ and ‘Output’ in describing the terminals has been replaced by Left Hand (LH) and Right Hand (RH).

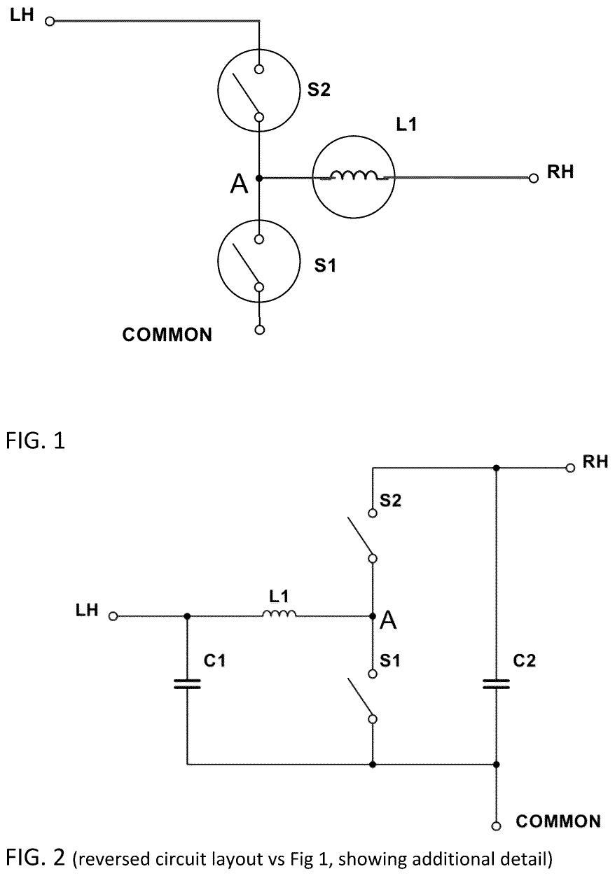

FIG. 1 shows the most basic directly coupled switched mode converter. In practice S1 and S2 are some type of semiconductor switch, these days commonly silicon MOSFETS, and if these are used then this circuit is intrinsically bi-directional.

In earlier technologies one of S1 or S2 might have been a bipolar transistor and the other a diode, and this technology would have limited operation to a single direction of current flow. Also, the current flow through the diode would have had irreducible power losses due to the forward voltage of the diode: one advantage of synchronous operation with MOSFET switches in each current path is that the voltage drop across a MOSFET when switched ON can be very much less than that of a diode. A further advantage is that with a fully synchronous converter the voltage relationship is determined, essentially independent of load, by the PWM relationship (shown below). With diodes a feedback mechanism is necessary to regulate the output voltage at low loads.

If the current flow is, as is conventional in circuit representations, from left to right, then FIG. 1 can be recognised as a voltage Down converter (or ‘Buck’ converter). The terminals LH (positive) and COMMON (Negative) form the input circuit, and RH (positive) and COMMON are the output circuit. As will be shown below the output voltage is always less than or equal to the input voltage (and the output voltage is practically always a bit lower because of power losses).

However, if the switch technology can sustain current in both directions, then this circuit can be run in reverse. Terminals RH and COMMON are the input circuit, LH and COMMON the output circuit, and the output voltage is always higher than the input voltage (actually in practice the lowest voltage on load is a little bit less than the input voltage because of the component losses).

This can be shown more explicitly by mirroring FIG. 1 about a vertical axis, to give FIG. 2.

Here the terminals notation has been swapped. With current flow left to right this can be recognised as a voltage Up converter, or ‘Boost’ converter. LH and COMMON now form the input circuit and RH and COMMON the output circuit, and the output circuit voltage is always higher than the input voltage (again the lowest output voltage will be a little bit less than the input voltage).

This again can be run backwards right to left and so operate as a Down or Buck converter.

In FIG. 2 the capacitive coupling to a ground or common rail is shown, which is desirable but not essential. In FIG. 1 this is not shown for simplicity.

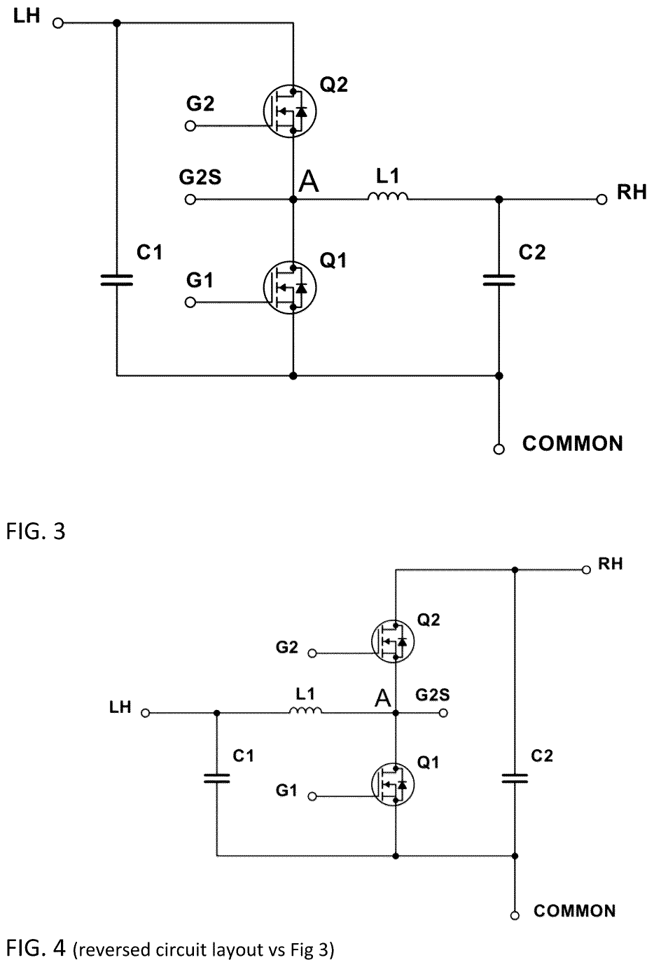

FIG. 3 shows the basic synchronous down converter circuit of FIG. 1 with S1 and S2 realised as N Channel MOSFETS and relabelled as Q1 and Q2 following mainstream electronics conventions. Generally N Channel MOSFETs are preferred over P channel MOSFETs because they have a combination of lower resistance when switched ON, and lower gate capacitance for a given ON resistance, but it is possible to implement this circuit with either type in any combination. The requirement is that the devices are connected such that their intrinsic diodes (shown explicitly in the right hand side of the component symbol) must be reverse biased with respect to the polarity of the input and output voltages. This will lead to a further difference in the Gate terminal drive requirements; to switch a MOSFET ON its Gate terminal has to be driven positively with respect to the Source terminal for an N Channel MOSFET and negatively for a P Channel device. With input and output voltages being positive with respect to COMMON the two general combinations are to have both Q1 and Q2 as N-Channel MOSFETS, or, and generally at lower powers, to implement Q2 as P channel MOSFET so that it can be driven with respect to the LH connection, which is the input voltage. There are four possible permutations, NN, NP, PN, PP.

FIG. 3 shows two further connections. The gate of Q1 is shown having a terminal G1 which must be driven positive with respect to COMMON to turn Q1 ON, and held at zero volts (or a small negative voltage) with respect to COMMON to ensure that it is turned OFF. Similarly, the gate of Q2 is shown with a drive terminal G2, but this must be driven in a similar fashion with respect to its SOURCE terminal, which is shown explicitly brought out to terminal G2S.

It is also possible to have versions of these circuits in which the input and output polarities are negative with respect to COMMON, and this gives a further factor two to the number of permutations.

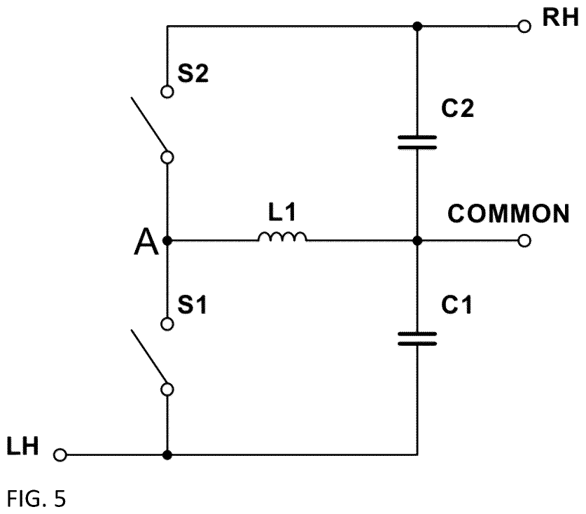

The direct coupled Down and Up converters cannot convert a positive voltage to a negative one, but for completeness this can be done with the Inverting converter of FIG. 5, which will convert a negative voltage at the LH terminal (with respect to COMMON) to a positive voltage at RH, or vice versa (but it would be conventional to invert the drawing so that a positive voltage was at the top and a negative one at the bottom).

The theory of operation of this sort of direct coupled switched mode circuit is well known in text books.

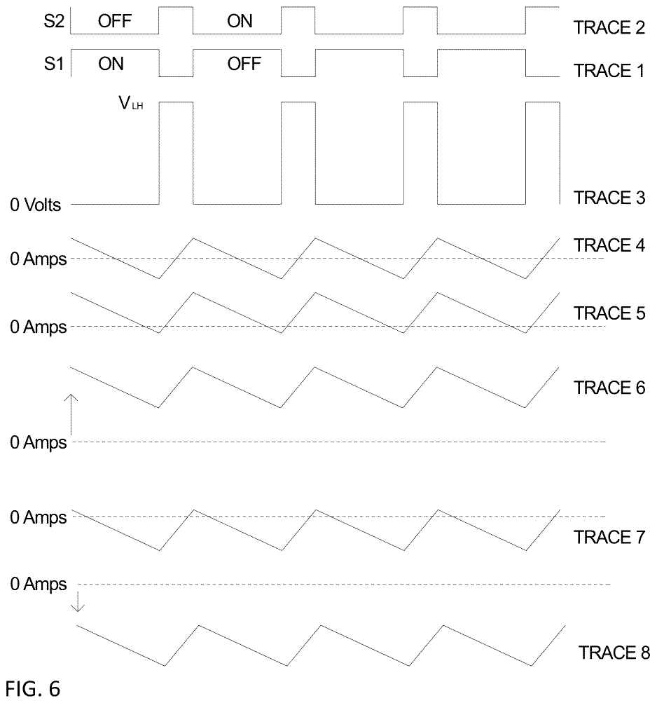

FIG. 6 gives a idealised view of synchronous converter operation for the case of the down (‘Buck’) converter of FIGS. 1 and 3. Traces 1 & 2 are the voltage signals (‘drives’) applied between Gate and Source of S1 and S2. Here S1 (Q1), the bottom switch is ON for longer than S2 (Q2) and they are never ON at the same time.

These signals are theoretical because the switching response of MOSFETs are finite and, as will be seen, if both are ON simultaneously then large currents can ‘shoot through’ both, potentially leading to device destruction.

But with that caveat, when S2, the upper switch is on, Trace 3 of FIG. 6 shows the voltage at A in the circuit (which is always where the two switching elements connect to one end of the inductor and is called the ‘Switching Point’ in the text below) rises to that of the LH supply. The voltage at C2 is lower, and so this will drive the current in the inductor to increase, as shown in each of the Traces 4 to 7 of FIG. 6.

When S2 is OFF and S1 is ON the voltage at point A will be reduced to close to zero (the COMMON voltage) and this will cause the current in the inductor to ramp downwards. In this simplified explanation it is assumed that the value of C1 and C2 are sufficiently large that their voltages are essentially constant across a switching cycle.

These traces describe the equilibrium condition when switching has been sustained for sufficient time for the voltages to stabilise: L1 and C2 comprise a series Resonant Circuit and if switching was suddenly switched on then this would generate transient ringing at the resonance frequency and the duration of the ringing would depend on whatever load was applied between the RH terminal and COMMON. However, in a typical system some control device generates the switching drive signals and so the currents and voltages can be built up in a controlled way with no significant resonant effect.

If the ON times of S1 and S2 are respectively t₁ and t₂ and the voltage at the input (LH) is V_{LH} and that at the output is V_{RH} then the equilibrium relationship is;

$$\frac{{V}_{R H}}{{V}_{L H}} = \frac{{t}_{2}}{( {t}_{1} + {t}_{2} )} \qquad EXP 1$$

(t₁+t₂) is simply the cycle time, and the RH expression is simply the PWM ratio, so this can be re-written;

$${V}_{RH} = PWM ratio * {V}_{LH} \qquad EXP 2$$

So, it can be understood that (in this idealised scenario) the output voltage is simply controlled, in a linear way, by the PWM ratio, from 0V to the LH voltage corresponding to the PWM ratio varying between 0% and 100%,

Depending on the power of the system the switching frequency might be in the range 50 kHz to 500 kHz and so the total cycle time might range from 20 usec down to 2 usec. The higher the frequency the smaller the passive filter components (capacitors and inductors) required but there are all sorts of loss mechanisms, all of which increase with frequency. For higher powers, where this invention is most applicable, a frequency of 100 kHz is typical, minimising component size but not yet having high losses, so the cycle time, (t₁+t₂), will typically be 10 usec.

Returning to FIG. 6, it is important to note that the shape and magnitude of the sawtooth waveform is determined by the LH and RH voltages and the value of the inductance L1, but is almost independent of the absolute magnitude of the current which is determined by EXP 2 acting on the resistances in the total circuit.

Here it should be noted that in a practical design the relationship of the magnitude of the total current to the amplitude of the sawtooth is a complicated matter. Every inductor has a ‘saturation current’ beyond which it cannot be magnetised further, and close to saturation its inductance will fall away rapidly, leading to the current to rapidly increase. So, the average current can be maximised if the amplitude of the sawtooth is small, but the peak is below saturation by some design margin. Minimising the sawtooth amplitude though requires bigger inductors, but then other factors have to be taken into account. The practical values selected will be dependent on cost, mass and volume, and steps in inductor and capacitor values of manufactured products. As a very broad rule of thumb the amplitude of the sawtooth might be in the range +/=10% to +/−30% of the sustained maximum rated current.

In FIG. 6, Trace 4, in which the area of the waveform under the zero current (‘0 Amps’) line is equal to the area above the line, represents the idealised situation for the converter switching, but with zero load. It can be seen that the average current shown by Trace 5 is positive at a relatively low load, and that Trace 6 represents a greater load with positive current (defined as current flowing into a load between the RH and COMMON terminals). Trace 7 shows a relatively light load for the converter running backwards, ie with a source of current between the RH and COMMON terminals and a load, or a battery between the LH and COMMON terminals. If the source of current on the RH side were a motor, and the device on the LH side were a battery, this would be a simple example of regenerative braking in an electric vehicle. Trace 8 shows a heavier current flowing from RH side to LH side.

The amplitude of the sawtooth waveform itself does not matter to this invention. The important point to note is that in traces 4, 5 & 7 the current waveform crosses through zero, and that means that both Q1 and Q2 (of FIG. 3) end their ON period with current flowing in the conventional direction through the switching device; which means that they can switch off cleanly. But in traces 6 and 8, one device (S2 in Trace 6 and S1 in Trace 8) switch off with the current flowing in the ‘anti-parallel’ direction. Operation in the modes of Trace 6 and Trace 8 is generally designated the ‘current’ mode (which will be used with that meaning here). The advantage of the ‘current mode’ is that the fluctuations in current relative to the average current are lower and require less filtering down and up stream (to smooth out the current at the final terminals) and because the average current can be pushed closer to the saturation current of the inductor. The vertical arrows on the LH side of traces 6 & 8 relate the zero current line (dotted) to the respective traces.

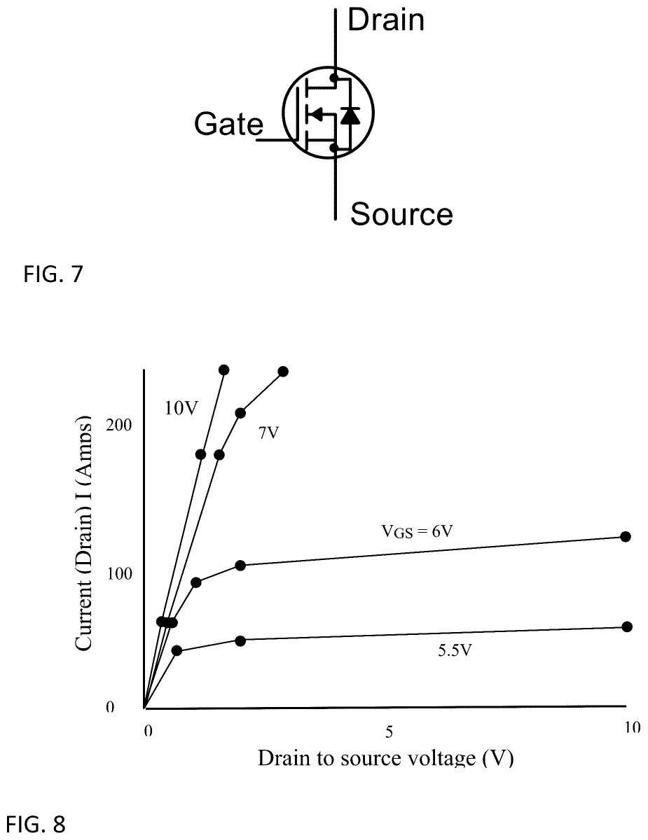

Before proceeding to the next level of detail it is necessary to review the basic operation of an enhancement mode MOSFET. FIG. 7 shows the general symbol for an N channel MOSFET with the Source, Drain and Gate terminals labelled. To the righthand side is the symbol of the intrinsic ‘anti-parallel’ diode. In a modern power MOSFET the current rating of this diode is matched to that of the main ‘channel’.

In an N channel enhancement mode device, if the Gate is at the same voltage as the Source then no current can flow if the Drain voltage is more positive than the Source, as the intrinsic diode is reverse biased. But if the Gate is at a positive voltage (typically 5-10V) with respect to the source then the switch closes and current can flow from Drain to Source and with a modern power device this can be a very low resistance connection, typically a few milliOhms. The forward voltage drop across this small resistance is typically a lot less than the forward voltage of a diode, thus allowing the efficiency advantage of this ‘synchronous mode’. Importantly the advantage is not just in greater power efficiency of the whole device, but in far lower heat generation, and thus a far lower demand for heat paths (‘heat sinking’) to keep the device junction temperature low. It is also common to parallel two or more devices to share the load and reduce the ON resistance and voltage drop further, something that it is not possible to do by parallel connecting diodes. With the Drain positive with respect to the Source this is the ‘conventional’ ON mode.

However, if the Source is more positive than then Drain by a sufficient voltage (typically about 1V) then the intrinsic diode will be forward biased and current will flow, but with the voltage drop which is characteristic of the diode and the magnitude of the current. As above, this is a power loss and generates a heat path requirement. But if the Gate is biased positively with respect to the Drain the MOSFET channel will turn on, with a reversed (‘anti-parallel’ direction of current flow) presenting the same low resistance path as in the forward mode, and shorting out the intrinsic diode.

FIG. 8 shows the forward transconductance characteristics of a typical MOSFET ON/OFF switching happens in the region above and to the left of the line labelled 10V, and by tracing the 10V line, which is almost straight, it is possible to read a voltage off the X axis and current off the Y axis and compute a very low channel resistance (typically measured in milliOhms) when the Gate-Source voltage is 10V.

It is this ability to short out the diode to reduce losses that is so important and is generally called the ‘Synchronous Rectifier’ mode. The table below summarises this information. The same principles apply to a P channel enhancement mode MOSFET with all the polarities reversed.

| | S positive wrt D | D positive wrt S |
|---|---|---|
| | Reversed | Conventional |
| G positively biased with | ON - low resistance | ON - low resistance |
| respect to S | | |
| G <= S voltage | ON - Diode voltage drop | OFF |

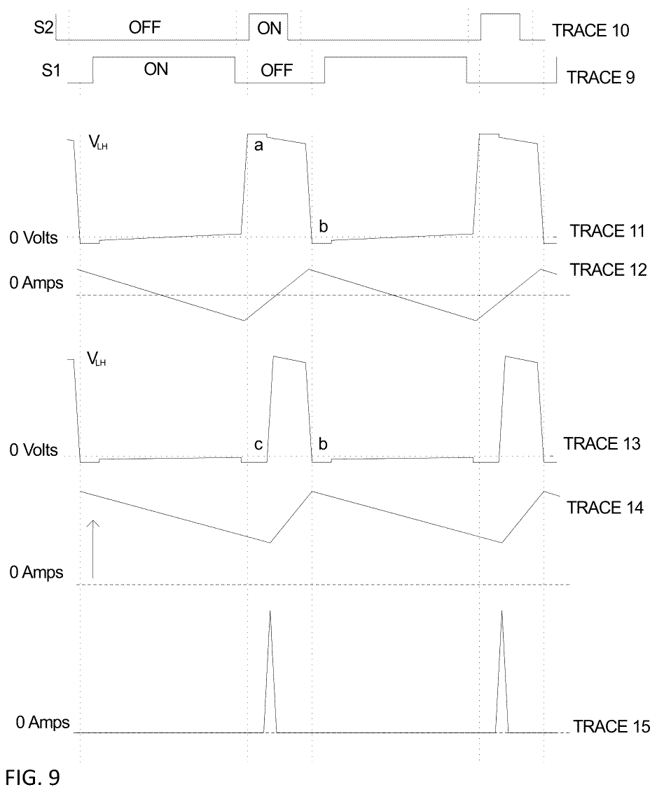

FIG. 9 shows modified drive signals to switches S1 and S2 in which there is ‘dead time’ in which both MOSFETS are held in the OFF state together so that they cannot both conduct current simultaneously, which would present very close to a short circuit across C1. If this happens huge currents can flow, almost certainly leading to the destruction of one or both S1 and S2. The dead-time is very exaggerated here for the purposes of explanation, it is typically about 1% of the cycle time. The horizontal scale is shown expanded by a factor 2 to show the detail.

Trace 9 and Trace 10 are modified versions of the drive signals shown in Traces 1 & 2. Trace 11 is a representation of the voltage at the switching point in the case of no load, thus a modified version of Trace 3. Trace 12 is the corresponding current signal, again showing a sawtooth waveform averaging to zero current. Trace 11 also represents the situation for light loads in which the current always crosses zero at some part of the cycle.

In the no load case there is no constant, DC, element of current flowing into the load and so the current trace has equal area above and below the zero current line. As each switch, S1 and S2, turns ON alternately, it will cause the ramp in the current to reverse.

If, as shown, positive current is defined as flowing from LH to RH, then when S2 is switched on the current will ramp up (become more positive), and when S1 is switched on it will ramp down, i.e. become more negative.

As a result, in the equilibrium state (and this is somewhat counter-intuitive at first) every ON period starts with current flowing in the opposite, or ‘anti-parallel’ direction for the MOSFET involved, but then the current ramps through zero and at the end of the ON period the current is flowing in the conventional direction for the MOSFET.

Now a MOSFET which is conducting in its conventional direction is very quick to switch off (for power MOSFETs this is tens of nanoseconds from the drive signal on the gate to the device switching off). But the action of an inductor is that its current in cannot be change quickly and so it continues to flow, and depending on the sense of current flow it is either driving electrical charge into point A of FIG. 3, or sucking charge out. There will be some capacitance between point A and COMMON and the power supply at LH given by the internal capacitances of the MOSFET, but these are small (and variable with voltage), and so there is a rapid voltage transition immediately after the MOSFET has switched OFF, driven by the current in the inductor. Looking in detail at the first upward voltage transition (at point A of FIG. 3), this happens almost immediately after the drive to S1 has switched off. But at this time S2 has not switched ON and so therefore the voltage ramps upward until the intrinsic anti-parallel diode in S2 turns ON, and thus the voltage at point A rises above the left-hand voltage and this is the little feature in Trace 11 labelled ‘a’. Then, when S2 switches ON the voltage can be seen to drop down to be just a bit above the left-hand voltage, this being the ‘synchronous rectifier mode voltage’ generated by the current flowing through the low resistance of MOSFET channel in the ‘anti-parallel’ direction. This small voltage excess over the LH voltage will now decrease as the current through the MOSFET, which is identical to that through the inductor, and thus shown in the rising ramp sections of Trace 12, decreases. At the point when the current is zero the voltage drop across the MOSFET will also be zero, and for the second part of the ON period for S2 the current will continue to ramp up, becoming more positive. As a result the voltage at point A will be a bit less than the LH voltage, with a small linear decrease towards the end of the conduction period. This is shown in an exaggerated fashion by the slopes of the ON and OFF period voltage waveforms in Traces 11 and 13.

At the end of the conduction period for S2, current through it is now in its conventional direction, and so it turns OFF cleanly. Current is now flowing positively in terms of the convention, into the inductor. When this current can no longer flow through S2 the removal of charge at point A will cause the voltage to drop rapidly until the intrinsic diode is turned on, at a voltage below the COMMON potential. This feature is labelled ‘b’. A bit later the Gate drive signal will go positive, turning on S1, shorting out the diode and reducing the voltage across S1. The current will now ramp down, and halfway through the conduction period the current will go through zero and become negative, which is current flowing backwards through L1, through S1 to the COMMON terminal. This negative current is however now in the conventional direction for S1, which when it switches off, does so cleanly, repeating the cycle.

This clean switching happens also at lower currents, in either direction, where the current waveform crosses through zero each somewhere in each cycle. But, as explained above, all inductors have a limiting saturation current, and a higher average current can be achieved if the amplitude of the current sawtooth is small compared to the average.

This situation is shown in FIG. 9, Traces 13 & 14 where the current is always positive (out through L1 to the load at the RH and COMMON circuit) shown by the positive offset to the 0 Amps line. The action when S2 switches off is identical to that for the zero-load situation in Traces 9 to 12. But the situation when S1 is due to switch off if very different. Here the Gate signal to S1 is such as to cause it to turn OFF. But the current through it is still positive (from LH to RH in FIG. 3), which is the ‘anti-parallel’ direction for S1. So, the current in the inductor is largely unchanged, transferring from the MOSFET channel to the anti-parallel (intrinsic) diode. At the point marked ‘c’ the voltage across the device is the diode forward voltage and the current continues to ramp downward as the stored energy in the inductor is discharged (there would be a slight inflection in the slope of that ramp, which would slightly increase (become more negative) because of the diode forward voltage.

Then, at the end of the deadtime S2 is turned ON, whilst S1 is still conducting through the diode. This is where the problem occurs that this invention solves. If the intrinsic diode within S1 were a perfect diode, then there would be no problem when S2 turned on, it would take over providing the current to the inductor, and in doing so it would reverse bias the diode in S2, which would switch OFF. But the diode is not perfect, it is slow to turn off and it will continue to conduct even when reverse biased, for a short time. Because the diode in S1 is still conductive, and S2 has been switched ON there is a very low impedance path through S2 and the diode in S1 in series, directly shorting C1, so huge currents can flow, running to several times the rated current of the devices. Such a spike is shown schematically in Trace 15 of FIG. 9. This is the current that is flowing straight through S2 and S1 in series and this is additional to the current through the inductor which transfers from the intrinsic diode of S1 to the conduction channel of S2.

These current spikes have the following effects;
1. They can in principle exceed the device capability and cause a device failure through excess current
2. They can excite the complex resonant circuits formed by the lead and track inductance, the device internal capacitances, and track and stray capacitances. This can give rise to very large oscillatory voltage waveforms at point A
3. These voltage waveforms may generate large, radiated signals that cause EMC problems (requiring screening to stop them getting out) and which may interfere with control signals inside the electronic product in which the MOSFETs are the switching part.
4. The oscillatory voltages may exceed the MOSFET voltage limit and cause device failure
5. The oscillatory voltages may couple through the GATE terminals leading to oscillatory switching of the main current path, increasing losses and thus causing heating.

In the time around point ‘c’, instead of switching S1 OFF, waiting a short period of dead time, and then turning S2 ON, it is proposed to switch S2 (or a separate parallel device) ON, but in a current limiting (or ‘constant current’) mode, prior to switching S1 off. The constant current in S2 needs to be higher than the current flowing in the inductor at the time and by a sufficient margin that it will subsequently allow capacitances associated with the switching point A to be charged sufficiently quickly to meet the requirement for a quick voltage transition.

It is very important to note that the current in the inductor cannot change very quickly and will be approximately constant during this new switching process (which in practice happens over about 100 nsec). Also, a MOSFET is naturally a transconductance device, so setting a particular Gate voltage will in principle put it into a near constant current mode

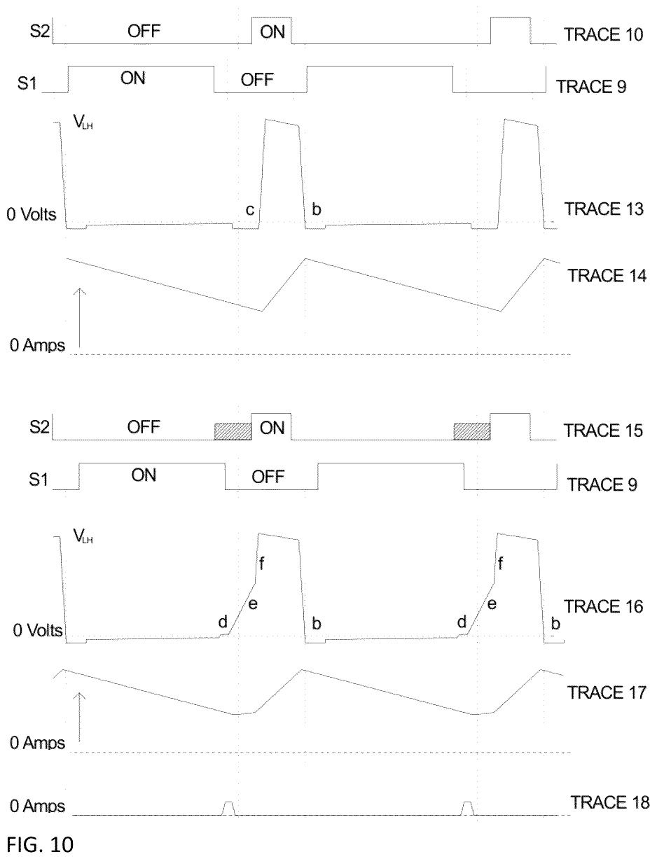

This process is depicted in an idealised manner in FIG. 10 (and again it is necessary to note that the horizontal scale is magnified around the complex transitions). Traces 9, 10, 13 and 14 have been replicated from FIG. 9 to make direct comparison easier. Trace 9 is copied again further down the page as this is (in principle) not changed in the invention.

Trace 15 though is modified compared to Trace 10 and a hatched area shows where S2, in the configuration of FIG. 3, representing the first embodiment of the invention, is switched partially ON by applying a voltage to the Gate terminal (with respect the Source terminal) that is sufficient to put it into a ‘constant current’ mode at the desired current. By reference to the device characteristics in FIG. 8 this will be lower part of the diagram, and by extrapolation, off the diagram to the right to far higher Drain Source voltages.

If the limited current is set somewhat higher than the current taken by the inductor, S2 will take over supplying current to the inductor and this is shown on Trace 16 which is the switching point (A) voltage. Because the inductor current cannot change quickly, it is possible to set a current that is higher and so S2 will now take all of the inductor current and the excess will flow through S1 which is still turned ON. But this current in S1 is now reversed in direction compared to the current when S1 was taking the inductor current; it is now in the conventional direction. Thus, the Drain of S1 will move to having a small positive voltage with respect to the Source. Because this voltage is positive the intrinsic reverse diode in S1 never switches ON, and S1 will now switch OFF cleanly. As soon as it switches off, S2 is capable of supplying current that is excess to that being conducted through the inductor, and so this will start to charge the capacitances associated with the Switching Point A (these are the Drain-Source capacitances of S1 and S2 and the ‘stray’ capacitances from interconnections and the physical Gate driver circuits). The voltage at A will start to ramp upwards, but at a lower rate compared to when S2 is turned fully ON. This lower ramping rate is shown by section ‘e’ of Trace 16. However as soon as S1 has switched OFF completely, S2 can be switched fully ON and this rapid change of voltage is shown in section ‘f’ of Trace 16.

Trace 17 of FIG. 10 shows the current waveform that will be slightly modified under the changed switching of the invention (this is schematic only, the exact shape will be determined by practical issues).

Trace 18 of FIG. 10 shows the current, which is the excess to that required by the inductor, which flows through S2 to S1 in the short period in which S2 is switched ON in the constant current mode (the hatched area) and S1 is still turned on.

The purpose of this invention is seen most clearly by comparing Trace 15 of FIG. 9 with Trace 18 of FIG. 10. Trace 15 shows a direct shoot-through current spike when S2 switches on whilst the intrinsic diode of S1 is conducting. This spike is essentially uncontrolled and can be destructive of the devices and will require them to be over-rated to withstand such spikes. Trace 18 shows a current pulse of very much lower amplitude which is, in principle, fully controlled. It is important to note that such controlled spikes are of such short duration (~50 nsec) they fully meet the ‘Safe Operating Area’ (SOA) requirements that are listed in all MOSFET data sheets and are also far lower amplitude than those of the uncontrolled ‘shoot through’. The energy dissipated in every pulse in Trace 18 represents a small but measurable power loss (and thus efficiency loss) but this has to be compared to the losses from uncontrolled shoot-through.

Of course this all happens very quickly and the faster it can be made to happen the better and it immediately becomes a practical design issue. All the components involved, the MOSFETS, the drivers, the voltage translators and the drive logic all have delays and the delays will be temperature dependent and have tolerances on them. But the requirement is simple, that there is a new element in the switching sequence, so that it always happens in the order below, across all temperatures and tolerances.
1. S2 switches into a constant current mode with a current excess over that being taken by the inductor
2. S1 switches OFF as soon as possible after its conduction direction becomes ‘conventional’
3. S2 switches ON fully as soon as possible after S1 has switched fully OFF

As explained above, this modified switching mode is not required if the current sawtooth waveform passes through zero in every cycle.

If the current through the converter was not crossing zero and was negative, representing a significant load in reverse, then the issue of reverse recovery would move to the other edge, and the roles of the switches S1 and S2 would be swapped, with S1 (or parallel device) going into the brief constant current mode. As also noted above, a ‘Down’ or ‘Buck converter with negative current flow is in fact an ‘Up’ or Boost converter seen back to front (left to right on the page. And so, in the case of heavy current, such that there is not a current waveform zero crossing, all permutations of converter are covered by this description with the rule that it is the transition where the current magnitude is least (the end of the discharge cycle) is where the new switching needs to be applied.

A discussion of implementation follows.

Returning to the generic N channel MOSFET characteristics of FIG. 8 and, taking, by way of example, the current values at a Drain Source voltage of 10, it can be seen that there is more than a 60A change of current for a half volt change of Gate voltage. Also, these characteristics will vary between device types, within and across batches, and with temperature. The requirement for the accuracy of the constant current in the hatched region of Trace 15 will differ across applications. In a given application it may be judged sufficient just to have an excess of current under all circumstances, which with tolerances might mean that the current is higher than ideal in other parts of the operating envelope, or across devices batches and temperature. At the other end of the spectrum the requirement might be for high accuracy in an adaptive system.

In an application where high accuracy is required, the overall operating controller can be designed such that at all times the magnitudes of the current are ‘known’ at the extremes of the sawtooth, both the low point and the peak. So, the requirement can be set that the constant current exceeds the current waveform magnitude low point by a margin that is algorithmically computable to suit the application. That value only changes slowly between cycles and so the task is to achieve that computed current value. There are four general strategies that can be described;
1. Mapping the Gate voltage from average device characteristics
2. Mapping the Gate voltage from calibration values from a given application device (at build or calibration time
3. By use of feedback from one or more cycles changing the drive value on subsequent cycles
4. By the use of feedback during a cycle, so that the Gate voltage is driven such that the Source current within a cycle matches that required.

These split into two groups, 1&2 do not use any feedback, 3&4 need a means of measuring the current in Source connection.

The first embodiment, already partially described, is that of FIG. 3 with a Gate drive that can take on an intermediate voltage value, and it can be understood from the description above that the current is very sensitive to the gate voltage, which will need to be tightly controlled.

The second and third embodiments use the technique of adding a source (sometimes called ‘degeneration) resistor (or commonly several resistors in parallel to spread the thermal stress and reduce inductance between the Source terminal), in the case discussed so far of S2 and the switching point A. This technique can reduce the sensitivity of constant current to the driver voltage by introducing some local direct feedback. The resistors are chosen such as to generate a voltage of a few volts when in constant current mode. Of course, such resistors constitute a huge source of inefficiency, and so they must be ON only for a very short time and switched out as soon as S1 has switched OFF properly. In the second embodiment they are shorted out by low voltage and low resistance MOSFETs and in the third embodiment a separate ‘helper’ MOSFET is used, just to do the constant current phase of the switching.

The invention will now be further described in the form of each of the embodiments.

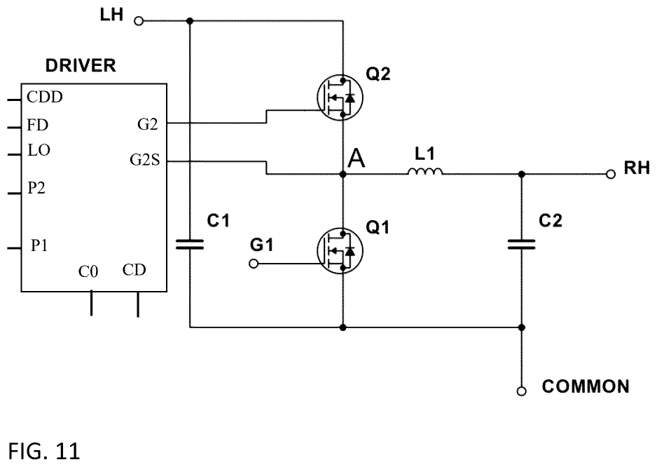

FIG. 11 shows the simple Down or Buck converter of FIG. 3 with a driver explicitly shown connected to the Gate terminal of S2, labelled G2, and the Source connection G2S.

The driver is shown in generic outline with the essential features. As can be seen the reference point for the Gate drive signal, the source of S2, G2S is connected to the switching point A and so is subject to the full switching voltage waveform. Most commonly the control systems for the converter will be referenced to COMMON. And so, it should be understood that all other terminals shown are galvanically isolated from G2 and G2S.

CCD is a logic signal referenced to L0 which is logic ground. When CCD is high the DRIVER will turn S2 partially ON in the constant current mode. FD is a logic signal that is also referenced to L0. When it is high the DRIVER will turn S2 ON in the full low resistance mode.

CD and C0 are envisaged as a digital bit stream (CD) and its reference (C0), (which might be connected to L0 at the overall controller) with the purpose of controlling the Gate voltage when in the Constant Current mode. There are many other ways of effecting this control, it might be an analogue signal, isolated via an opto-coupler, or even a high impedance current drive. Digital communication is probably preferred and might typically also allow connection from the DRIVER to the overall system control by an additional data line, so that the driver status can be monitored.

These signals are typically isolated within the driver using high speed opto-couplers.

P1 and P2 are a source of power for the driver, typically a high frequency AC signal that can be isolated through a transformer and rectified to give a DC power supply of about 10 Volts that is isolated from COMMON and referenced to G2S.

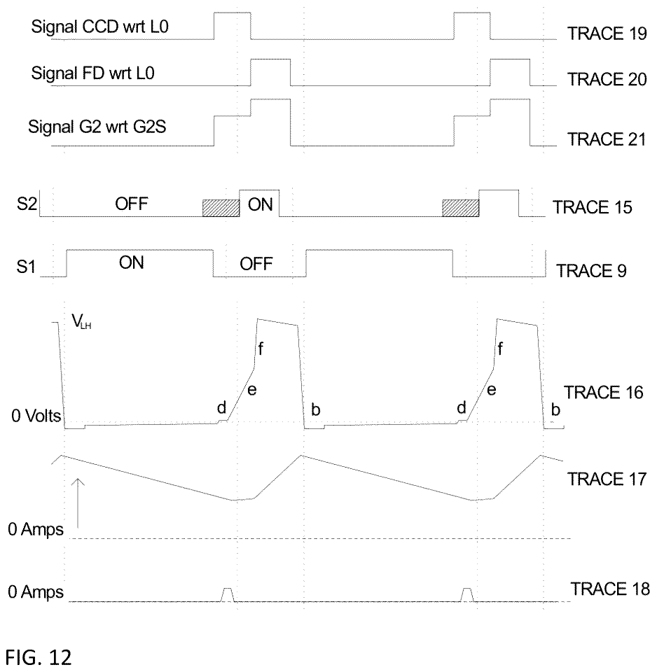

FIG. 12 is the timing diagram for the first embodiment. It retains some of the traces of FIG. 10 but adds those used with the driver. Trace 19 shows the logic signal CCD which will turn S2 ON into the constant current mode. Trace 20 shows the logic signal FD that turns S2 fully ON and Trace 21 shows the two-level Gate drive signal G2 for S2.

It should be noted that the horizontal scaling has been exaggerated; in reality the duration of CCD is very short, and that of FD is variable, according to the PWM ratio. Also, the timing has been shown idealised, practical component delays are not shown.

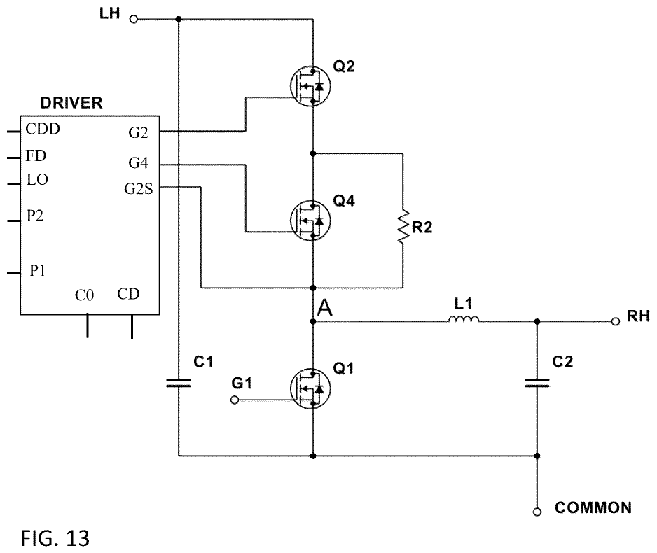

The second embodiment is shown in FIG. 13 and uses a resistor R2 (or several in parallel) in the Source to switching point connection (for S2) or Source to COMMON connection (for S1). R2 has Q4 connected in parallel, so that when Q4 is switched on, R2 is ‘shorted out’ to the very low resistive value of Q4 when ON.

Q4 can have a very low voltage rating because it never is subject to a Drain Sources voltage higher than Q2's Gate driver output voltage, and such low voltage MOSFETs are available with extremely low ON resistance. The driver shown on the schematic has one additional output, G4, to drive the Gate of G4.

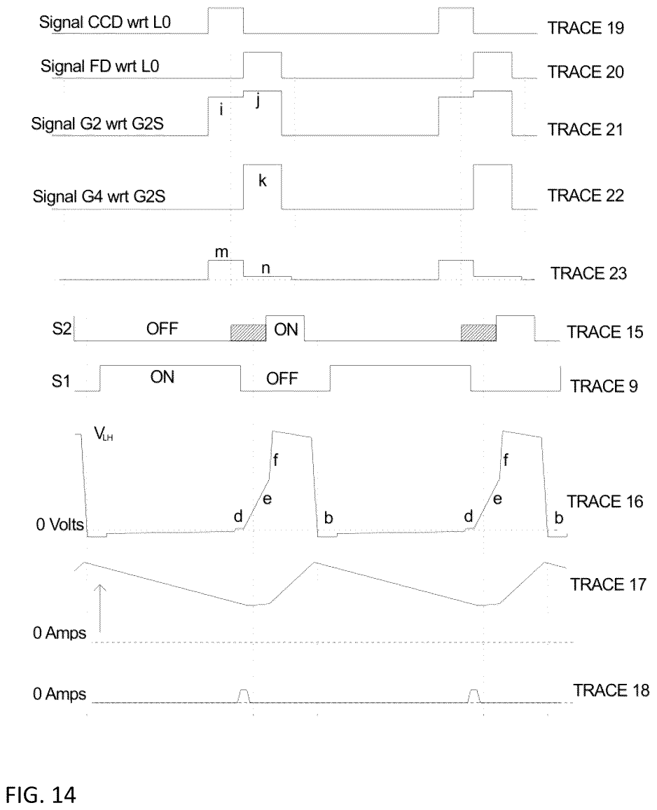

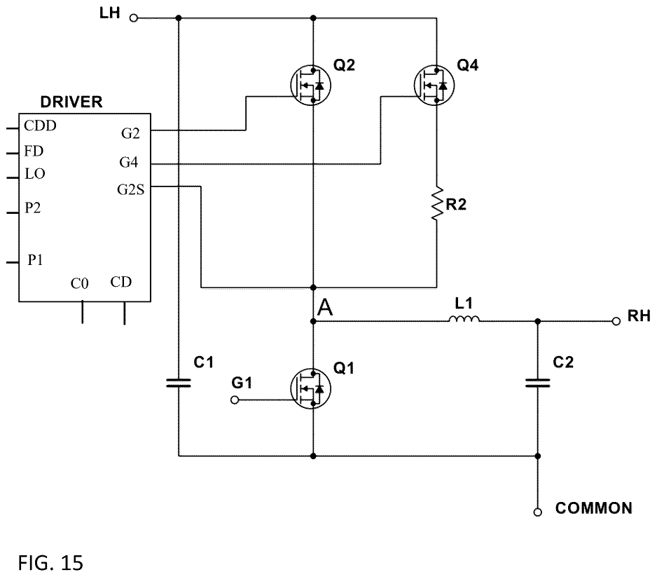

FIG. 14 shows the timing diagram. The G2 signal has the same two-level form as in the first embodiment, but the second, higher level is shown as a higher voltage because in this period (labelled ‘i’) Q4 is switched OFF and the Source terminal of Q2 is at the voltage generated by the current over the resistor R2 (this voltage is shown as period ‘m’ in Trace 23. Then, when S1 has fully switched OFF both Q2 and Q4 are turned fully ON. In this arrangement there is a small reduction in total efficiency because of the series resistance the new shorting MOSFETs. The prime advantage of this embodiment is the reduction in sensitivity of the current set in the constant current mode to the Gate drive voltage because of the addition of the resistor. It also does not need additional switches that are rated to the full working voltage. A further advantage is that some of the power dissipation whilst the MOSFET is in the constant current mode now occurs in the resistors. A practical disadvantage is that additional components are required, and, due to the characteristics of the packaging of the main switching MOSFETs and those that might act as shorting MOSFETs tends to be different, thus making a practical realisation on a PCB more challenging. This embodiment might be seen as advantageous over the first embodiment because the reduction in sensitivity means that the constant current can be actively mapped without needing feedback.

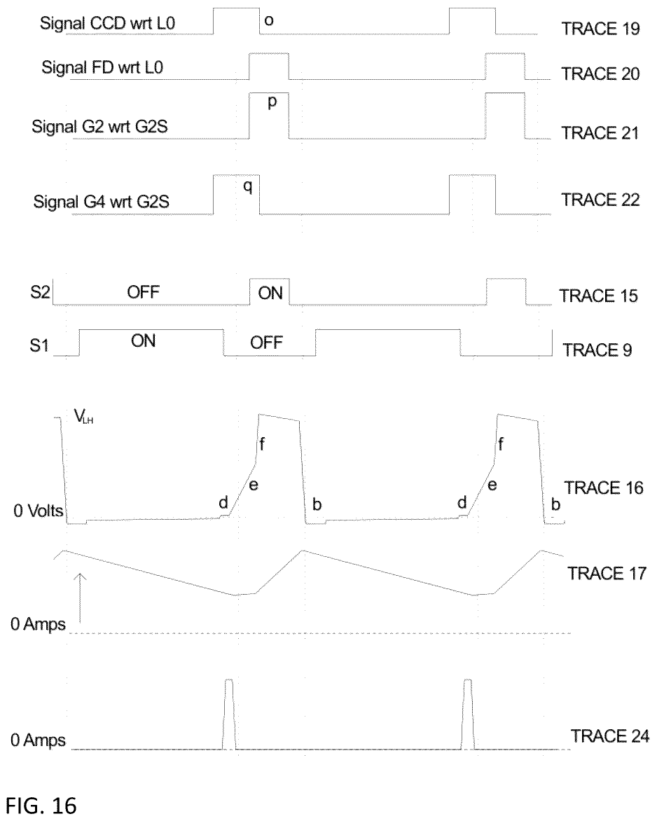

The third embodiment is shown in FIG. 15 and the corresponding timing diagram in FIG. 16. It re-arranges the components of the second embodiment. It also overcomes some of the practical issues of the second embodiment. Instead of trying to limit the current through the main switching MOSFETs it adds one (or more) parallel ‘Helper’ MOSFET, which can conveniently be of the same type as the main switching MOSFETs (giving both parts commonality and a common mounting technology). The Helper MOSFET has a resistor in the source connection, helping make the ‘constant current’ more stable against changes in Gate voltage. They are only switched ON for a short time (although the timing of when they are switched OFF is now not at all critical, so long as it happens no later than S2 switching OFF). As with the second embodiment, as soon as S1 has fully turned off, Q2 can be fully switched ON. The Gate voltage supplied to G4 when it is ON can be the full Gate voltage available, thus relying in the MOSFET characteristics and value of R2 to set the ‘constant current’ or, and better, the level of the G4 can be set adaptively to optimise the performance of the whole converter.

In the timing diagram FIG. 16 it can be seen that Trace 19 has been altered so that the logic signal CCD that commands constant current has been extended at the trailing end (labelled ‘o’) so that is now overlaps the period of FULL ON switching to S2 in commanded by logic signal FD shown in Trace 20 which is unmodified. The gate drive signal G2 that switches Q2 ON now is always the full available gate voltage, corresponding to timing of signal FD (labelled ‘p’) (practical delays are not shown). Similarly, the gate drive G4 to Q4 now exactly corresponds to the timing of signal CCD. It may be the full available gate voltage, in which case setting of the ‘constant current’ will rely on the choice of R² and will be fixed. But advantageously the voltage when G4 is high can be made adaptively variable so as to set the constant current to optimise performance of the whole converter. Trace 24 now shows the current flowing in Q4. This has the same timing as the small current pulses shown in Trace 18 in all the above timing diagrams, but, whereas the amplitude scaling in Trace 18 was intended to show comparison of the controlled constant current pulse in Trace 15, trace 24 has now been rescaled to show an approximately correct relationship to the current scaling of Trace 17 in FIG. 15. Thus, while Q4 is switched ON it is supplying more current than the inductor is taking.

The three embodiments have now been described in the context of the Down or ‘Buck’ converter which is operating in the forward direction, ie with current and power flowing from left to right, and without explicitly showing how the actual current in the ‘constant current’ mode can be detected and used, in feedback to control it more precisely.

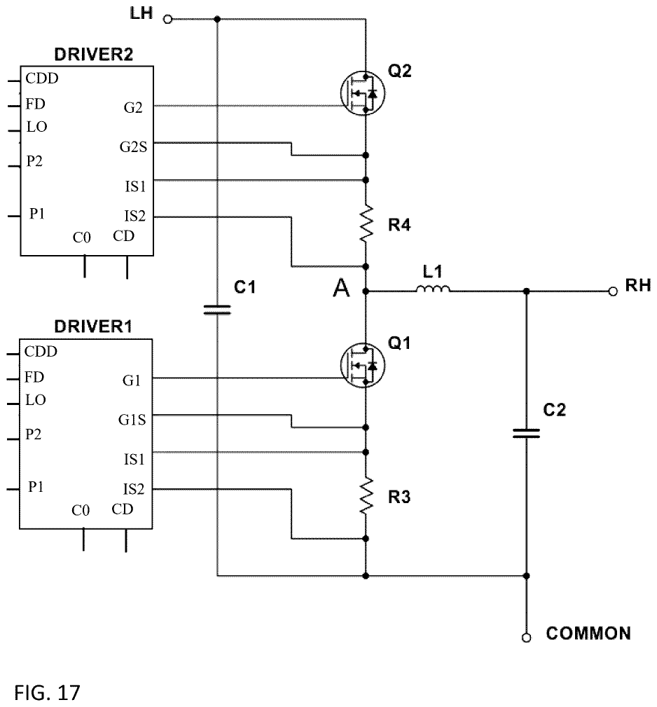

To show the three embodiments equipped to use the invention in a bi-directional mode, and how the current for feedback can be sensed, FIGS. 17, 18 and 19 show the basic schematics of the three embodiments. As noted above a Down converter running backwards is identical to an Up converter running forwards, just viewed in the mirror, effecting a left-right swap.

FIG. 17 shows the first embodiment implemented on both the bottom and top MOSFETs, Q1 and Q2. Each is now equipped with a current sensing resistor, respectively R3 and R4. Since these are permanently in the main conduction path, they constitute a further loss of efficiency, and so their ohmic value will be kept as low as is compatible with having a reliable current signal. Typically these resistors will have values of the order 1 milliOhm. Two drivers are shown, which are advantageously identical, each equipped with two extra terminations, IS1 and IS2 that allow sensing of the small voltage (typically millivolts or tens of millivolts) generated over the sense resistors.

Some small but significant changes are also shown. The return G2S for Gate drive G2 was shown as connected to the switching point A in FIG. 11, to which the Gate of G2 was connected. It is now shown connected directly to the Source of G2. This has two benefits, the first being that the Gate drive signal is applied directly where it is needed without the small bit of negative feedback that would be generated by the voltage across R4. The second benefit is that the return drive current is not mixed in the signal representing the source current. Similarly, G2S and IS1 are shown connected to the same place but by different routes; in a real design the driver and Q2 and R4 will be separated and the connections will not have zero ohmic resistance, and certainly non-zero inductance, and so the small voltage between IS1 and IS1 is not contaminated by the driver return current acting on the non-zero impedance.

The same connections and considerations apply to Q1, R3 and Driver 1.

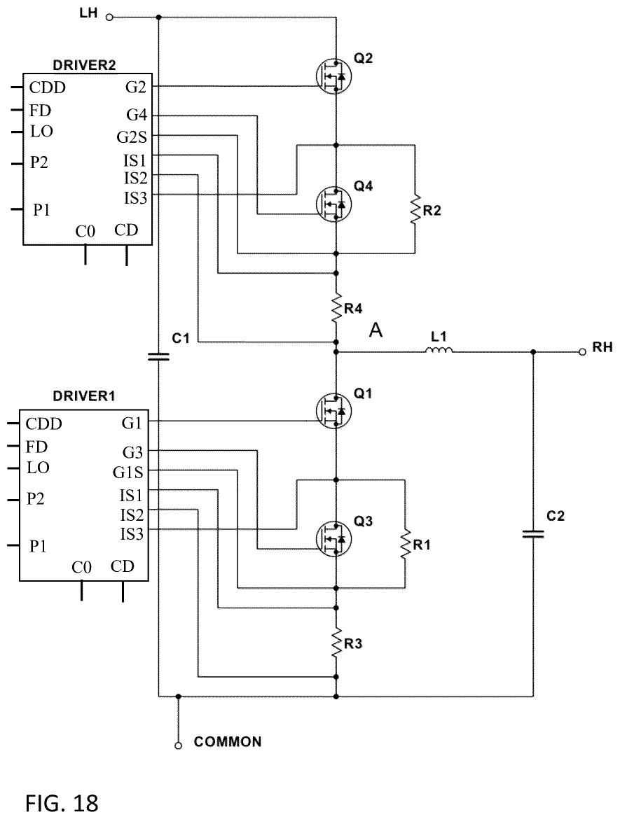

FIG. 18 shows the second embodiment with both the top and bottom of the half-bridge equipped to use the invention. Shown here are the same R3 and R4 low value current sensing resistors connected via current sensing terminals in the drivers; here they are optional because the total current through the device might be sensed elsewhere, in which case IS2 need not be connected. But the driver adds another connection, IS3 which senses the much greater voltage across the ‘degeneration’ resistors R1 and R2 and this can be referenced to connection IS2. The voltage generated by these resistors is typically a few volts, whereas that across the current sensing resistors R3 and R⁴ is a few tens of millivolts. Thus, sensing across R1 or R2 is very much easier to provide feedback for control of the ‘constant current’ mode.

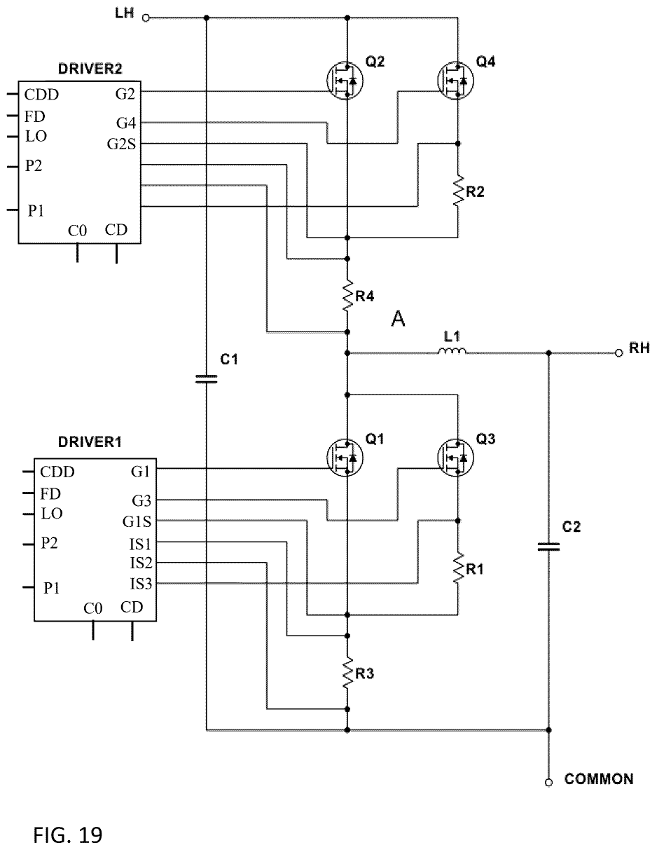

FIG. 19 shows the third embodiment equipped top and bottom to use the invention, with essentially identical feedback connections, as described for the second embodiment.

This description of the invention, in its three embodiments and with descriptions of the various permutations of top and bottom implementation of the device is for forward and backward current flow. As so far described the problem of shoot through currents at the end of the discharge cycle of the inductor happens if the current has not crossed through zero and therefore with a MOSFET switching device conducting in the ‘unconventional’ or ‘anti-parallel’ direction at the end of its conduction period. Current flow switches to the intrinsic anti-parallel diode and it is the propensity of such devices to continue conducting for a short period even after being reverse biased. Thus in the description above the logic control need only enable the action of the invention in these circumstances, and so it will happen once per cycle, on one of the two edges of the voltage waveform at point A.

However, this invention is also applicable to a second, separate problem with these sorts of MOSFETs; that the turn ON time of the intrinsic diode is very small but non-zero. The invention so far described is very effective at cleaning up the switching at point A to the extent that the oscillatory ‘ringing’ of the voltage at point A can be very effectively controlled. It will then be noticed that there is small but significant ringing on the other transition, at the point marked ‘b’ in many of the timing diagrams. In this transition the voltage change at A is caused by the current in the inductor discharging the capacitances at A, so that the voltage falls rapidly. It will continue to fall until some semiconductor device switches ON. This could be achieved if the device that is going to turn on next were to turn on before the voltage at A had been driven below the COMMON voltage (as described above, or above the supply voltage on the other transition). But the practical problem is that this inductor driven voltage transition happens very quickly and it is practically very difficult to ensure that the dead-time between S2 and S1 being ON is shorter than the inductor driven transition time.

So, it is common practice that the intrinsic MOSFET diode is used to ‘catch’ the transition, turning ON just as the voltage exceeds its forward voltage, as shown by the feature ‘b’ on the timing diagrams where the voltage goes below the COMMON voltage for a short time by the amount of the forward voltage of the diode. This diode conduction ends when the MOSFET that is about to conduct actually turns ON (Q1 in the description above).

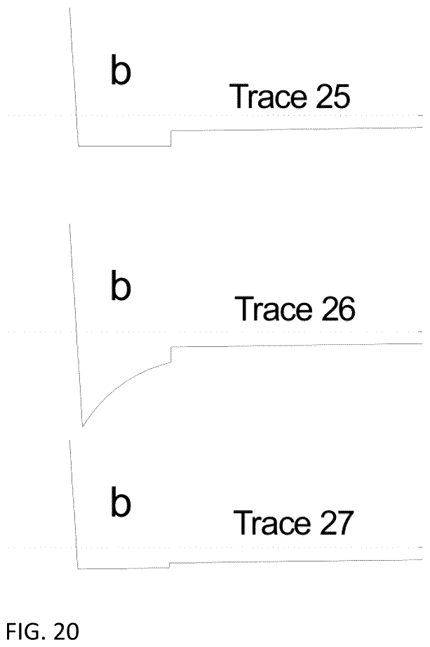

FIG. 20 shows the point ‘b’ from timing diagrams in FIG. 9 onwards in an expanded scale. Trace 25 shows the voltage trace at the switching point, point A, as drawn in the timing diagrams following common expectation on this edge.

Trace 26 shows in exaggerated form the actual voltage waveform shown with a very fast oscilloscope, where, to the finite switch on time of the diode the voltage exceeds the forward voltage of the diode and creates a voltage spike which in turn starts oscillatory ringing.

Trace 27 shows in idealised form the voltage waveform that might be achieved by this invention on this edge. The constant current mode would be turned on to a current exceeding that being taken by the inductor. Because the current is limited, concerns about shoot-through from timing tolerances of deadtime are controlled. The MOSFET Q1 would then be switched ON in a constant current mode at the time that the voltage transition would pass through the COMMON voltage (indeed the fact that the current exceeds the current taken by the inductor it would accelerate the rate of transition) and thus the mechanism for an overshoot is minimised. When S1 turns fully ON the small voltage that A is with respect to COMMON will be reduced further.

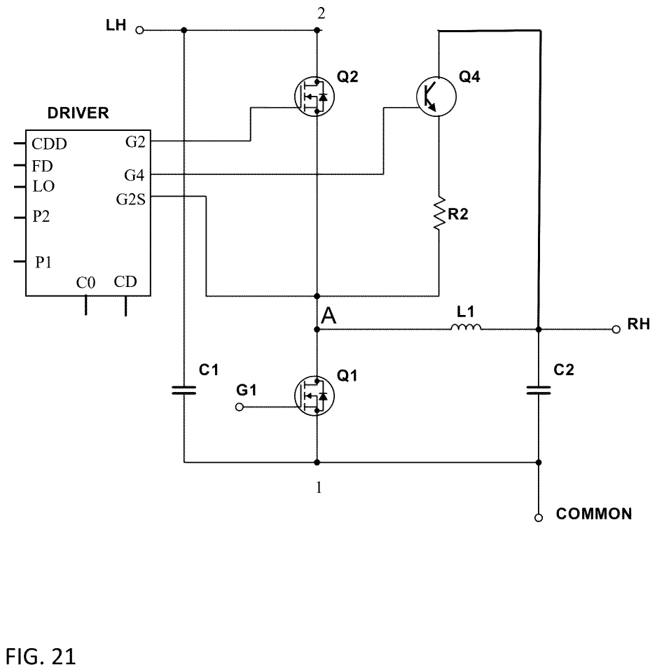

FIG. 21 shows another embodiment of the invention. In this case the source of current used to draw the voltage of the switching node away from terminal 1 (the terminal of Q1) is not terminal 2 (the terminal of Q2) but rather the terminal outboard of the inductor. Note that Q4 should prevent current flowing in both directions when turned off (E.g. a bipolar transistor could be used). One advantage of this approach is that it suits down and up conversion with only three transistors rather than four. In general, any suitable source of current could be used to draw the voltage away from terminal 1, and the one terminal that cannot be used is terminal 1. In general, any suitable source of current could be used to draw the voltage away from terminal 2, and the one terminal that cannot be used is terminal 2.

More generally in a voltage converter device a switching node connects to first and second transistor components and an inductor to control a voltage or current difference between the upper terminal and the inductor terminal. At high load conditions, the inductor drives current through the first transistor components whilst it is turned on, thereby tending to drive it towards being in forward bias ahead of the second transistor component turning on. The second transistor component turns on in a current limited mode permitting enough current to prevent the transistor component being in forward bias in order to prevent shoot through when the second transistor component turns fully on. The second transistor component turns on in its current limited mode whilst at or before the point when the first transistor component turns off (preferably whilst the first transistor component is still fully on) This enables the second transistor to adjust the voltage of the switching node to prevent the first transistor remaining in forward bias, whilst permitting the switching time to be minimised.

It will be understood that the present invention has been described above purely by way of example, and modification of detail can be made within the scope of the invention.

Moreover, the invention has been described with specific reference to voltage converters. It will be understood that this is not intended to be limiting and the invention may be used more generally in any device that contains a voltage converter. For example, the invention may be used more generally in a power supply of an electrical motor (where the windings of the motor are the inductive component) and so on. Additional applications of the invention will occur to the skilled person.

For avoidance of doubt, the disclosure contemplates that the features of each dependent claim may be implemented in combination with the subject matter of each originally referenced base claim, and that the embodiments are mutually combinable including (but not exclusively) as set out here: embodiments of claim 3 with those of any one of claims 1-2; embodiments of claim 5 with those of any one of claims 1-4; embodiments of claim 7 with those of claim 5 or claim 6; embodiments of claim 8 with those of any one of claims 1-7; embodiments of claim 9 with those of any one of claims 1-8; embodiments of claim 11 with those of any one of claims 1-10; embodiments of claim 12 with those of any one of claims 1-11; embodiments of claim 13 with those of any one of claims 1-12; embodiments of claim 14 with those of any one of claims 1-13; embodiments of claim 15 with those of any one of claims 1-14; embodiments of claim 20 with those of any one of claims 1-19; embodiments of claim 21 with those of any one of claims 1-19; embodiments of claim 22 with those of any one of claims 1-19; embodiments of claim 23 with those of any one of claims 1-22; embodiments of claim 24 with those of any one of claims 1-22; embodiments of claim 25 with those of any one of claims 1-24; embodiments of claim 26 with those of any one of claims 1-25; embodiments of claim 29 with those of any one of claims 1-28; embodiments of claim 34 with those of any one of claims 1-29. These combinations are disclosed as optional implementations that may be practiced individually or in any technically compatible combination described herein.

1. A voltage converter device comprising:
a circuit element comprising:
a first transistor component being an intrinsic diode transistor component, connecting a switching node to a first terminal for a first voltage; and
a second transistor component, connecting the switching node at least to a second terminal for a second voltage;
an inductive component, connecting the switching node to a third terminal for an intermediate voltage; and
a control circuit arranged to cyclically control the intrinsic diode transistor component to be in at least off and on states, and the second transistor component to be in on, off, and intermediate states, in the following order:
an energising period defined by the second transistor component being on, and intrinsic diode transistor component being not being on, for energising the inductive component;
a post-energising period defined by neither being on;
a de-energising period defined by the intrinsic diode transistor component being on, and the second transistor component not being on, for permitting the inductive component to draw or drive current through the intrinsic diode transistor component; and
a pre-energising period defined by neither being on, with the second transistor component being for at least part of the time in its intermediate state;
wherein the second transistor component is arranged such that, in use, in the intermediate state it supplies or draws current to or from the switching node, and respectively from or to a voltage terminal comprised in the voltage converter, such as to pull the voltage of the switching node away from the voltage of the first terminal, in the direction of the voltage of the second terminal;
characterised in that:
the second transistor component is arranged, and the control circuit is arranged to control it, such that, in use, the intermediate state of the second transistor component is activated substantially at or before the end of the de-energising period; and
node away from the voltage of the first terminal, in the direction of the voltage of the second terminal;
characterised in that:
the intermediate state of the second transistor component is activated substantially at or before the end of the de-energising period; and
wherein in the intermediate state, the second transistor component conveys substantially the same or more current to or from the switching node, than that respectively conveyed from or to it by the inductive component.
Activating the intermediate state of the second transistor component whilst the first transistor component is fully on is a marked departure from the prior art which emphasises the need for a non-zero amount of dead time where neither device is on.
By doing this the intermediate state is able to adjust the voltage of the switching node such that the first transistor component isn't (or ceases to be) in forward bias, whilst minimising the time that neither transistor component is fully on, thereby greatly improving electrical performance.
Ensuring the intermediate state is active throughout the pre-energising period helps ensure that the current it supplies to the switching node drives (and sustains) the voltage of that switching node away from the region which would otherwise cause the first transistor component to be in forward bias which could cause it to have an activated internal diode. Any variation in the strength of the intermediate state (E.g. any reduction in the conductivity of the electrical path by which it supplies/draws current) should a avoid any dip that would cause the first transistor to be forward biassed, and this is especially important to avoid at the end of the pre-energising period (which is what US2018294723 describes).
wherein in the intermediate state, the second transistor component conveys substantially the same or more current to or from the switching node, than that respectively conveyed from or to it by the inductive component.

2. The voltage converter device according to claim 1, wherein the second transistor component is arranged, and the control circuit is arranged to control it, such that, in use, the intermediate state is active at the beginning substantially throughout the pre-energising period.

3. The voltage converter device according to claim 1, wherein the first transistor component and control circuit are arranged to provide, in use, a change in state of the first transistor component from fully on to fully off at the end of the de-energising period, substantially as a binary state transition.

4. The voltage converter device according to claim 1, wherein the second transistor component and control circuit are arranged to provide, in use, the intermediate state by setting the gate-to-source voltage of a transistor of the second transistor component, to be within the region of the transistor in which the drain source current is substantially determined by the gate source voltage.

5. The voltage converter device of claim 1, wherein the intermediate state of the second transistor component is activated before the end of the de-energising period.

6. The voltage converter device of claim 5, wherein control circuit is adapted to control the second transistor component to be substantially fully off from a time proximal to the beginning of the de-energising period until being activated at a time proximal to the end of the de-energising period.

7. The voltage converter device of claim 5, wherein substantially throughout the period of from the end of the de-energising period to the end of the pre-energising period, the current conveyed by the second transistor component to the switching node is substantially the current conveyed from the switching node to the inductive component, and substantially throughout the period of from when the intermediate state is activated to the end of the de-energising period the current conveyed by the second transistor component to the switching node substantially exceeds the current conveyed from the switching node to the inductive component.

8. The voltage converter device of claim 1, wherein the second transistor component is arranged, and the control circuit is arranged to control it, such that in use, during the pre-energising period, the voltage of the switching node is adjusted from a voltage outside of the range of the first terminal voltage to the second terminal voltage, in the direction of the first terminal voltage so as to be in the range of the first terminal voltage to the second terminal voltage, by the end of the de-energising period.

9. The voltage converter device of claim 1, wherein the second transistor component is arranged, and the control circuit is arranged to control it, such that in use, from the activation of the intermediate state of the second transistor component to the end of the pre-energising period, the charge conveyed from the second transistor component to the switching node is substantially the sum of:
a first component of charge, being that conveyed from the switching node to the inductive component, minus any charge conveyed from the first transistor component to the switching node; and
a second component of charge that is in the range of:
the capacitance(s) of the switching node times the voltage of the first terminal minus the voltage of the switching node at the start of the intermediate state period; and
the capacitance(s) of the switching node times the voltage of the second terminal minus the voltage of the switching node at the start of the intermediate state period.

10. The voltage converter device according to claim 9, wherein the second of the two components of charge is closer to the capacitance(s) of the switching node times the voltage of the second terminal minus the voltage of the switching node at the start of the intermediate state period, than to the capacitance(s) of the switching node times the voltage of the first terminal minus the voltage of the switching node at the start of the intermediate state period.

11. The voltage converter device of claim 1, wherein the intermediate state is configured such that, in use, from the intermediate state being activated to the end of the pre-energising period, the sum of the charge conveyed by the second transistor component between the switching node and the terminal of the second transistor component and/or third terminal, minus any charge conveyed between the switching node and the terminal of the intrinsic diode transistor component, exceeds the charge conveyed by the inductive component between the switching node and the third terminal, by at least a factor of 1.5.

12. The voltage converter device of claim 1, wherein the intermediate state is configured such that, in use during the pre-energising period, it adjusts the voltage of the switching node to be proximal to the second voltage, by the end of the pre-energising period.

13. The voltage converter device of claim 1, wherein the control circuit is arranged to measure the voltage at the switching node, or the current through the inductor, during one or more previous cycles, and to supply any of a predetermined range of gate voltages for holding the energised transistor component in the intermediate state, during the pre-energising period in accordance with an operating map.

14. The voltage converter device of claim 1, wherein the control circuit is arranged to measure the voltage at the switching node, and to adjust a gate voltage for holding the energised transistor component in the intermediate state during the pre-energising period, based on a variation of the gate voltage from a predetermined target voltage, during the one or more previous cycles.

15. The voltage converter device of claim 1, wherein the means to permit the second transistor component to be held in an intermediate state, comprises an electrical circuit comprised in the second transistor component, comprising at least two transistors with associated electrical paths and resistances thereof, at least one being connected to the terminal associated with the second transistor component, and the other being connected to either that same terminal or the third terminal, the at least two transistors being arranged such that three predetermined combinations of their on and off states, respectively provide the off state, intermediate state, and on state, of the second transistor component, for being cyclically held in those states by a control circuit.

16. The voltage converter device of claim 15, wherein, in the electrical circuit one transistor thereof is connected to the terminal associated with the second transistor component, and another transistor thereof is connected to the third terminal.

17. The voltage converter device of claim 15, wherein, in the electrical circuit, both of the transistors are connected to the terminal associated with the second transistor component.

18. The voltage converter device of claim 17, wherein the at least two transistors with associated electrical paths and resistances, are arranged in series.

19. The voltage converter device of claim 17, wherein the at least two transistors with associated electrical paths and resistances, are arranged in parallel.

20. The voltage converter device of claim 1, being arranged to operate as a down converter, wherein in operation as a down converter, the first terminal has a low voltage, and the second terminal has a high voltage.

21. The voltage converter device of claim 1, being arranged to operate as an up converter, wherein in operation as an up converter, the first terminal has a high voltage, and the second terminal has a low voltage.

22. The voltage converter device of claim 1, being arranged to operate as a down converter, wherein in operation as a down converter, the first terminal has a low voltage, and the second terminal has a high voltage;
wherein the second transistor component is a second intrinsic diode transistor component operable to be in on, off and intermediate states, and the voltage converter is further arranged to operate as an up converter, and wherein in use as an up converter the control circuit is arranged to cyclically control the first and second transistor components, through the following states in the following order:
an energising period defined by the first transistor component being on, and second intrinsic diode transistor component being not being on, for energising the inductive component;
a post-energising period defined by neither being on;
a de-energising period defined by the second intrinsic diode transistor component being on, and the first transistor component not being on, for permitting the inductive component to draw or drive current through the second intrinsic diode transistor component; and
a pre-energising period defined by neither being on, with the first transistor component being for at least part of the time in its intermediate state;
wherein the first transistor component is arranged such that, in use, in the intermediate state it supplies or draws current to or from the switching node, and respectively from or to a terminal comprised in the voltage converter, such as to pull the voltage of the switching node away from the voltage of the second terminal, in the direction of the voltage of the first terminal;
wherein the intermediate state of the first transistor component is activated substantially at or before the end of the energising period; and wherein in the intermediate state, the first transistor component conveys substantially the same or more current to or from the switching node, than that respectively conveyed from or to it by the inductive component.

23. The voltage converter device of claim 1, wherein the second terminal provides a ground or common voltage rail, that is capacitively coupled to the first terminal, and capacitively coupled to the third terminal, such that the three terminals share a common or ground rail.

24. The voltage converter device of claim 1, being a galvanically isolated voltage convertor in which the inductive component is a coupled inductor connected to the third terminal for an intermediate voltage.

25. The voltage converter device of claim 1, wherein the control circuit is adapted to detect the load on the voltage converter, and to operate in at least two modes depending on a detected load, including a high load mode where the control circuits controls the second transistor component to be in its intermediate state during the pre-energising period, and a low load mode where the control circuit controls the second transistor component to be off during the pre-energising period.

26. The voltage converter device of claim 1, wherein the (or each) diode transistor component comprises a Silicon MOSFET or a Silicon Carbide MOSFET.

27. The voltage converter device of claim 26, wherein the (or each) diode transistor component comprises a Silicon MOSFET.

28. The voltage converter device of claim 26, wherein the (or each) diode transistor component comprises a Silicon Carbide MOSFET.

29. The voltage converter device of claim 1, wherein the control circuit is arranged to activate the intermediate state of the second transistor component before the end of the de-energising period.

30. A method of controlling the voltage converter device of claim 1, comprising the step of controlling the intrinsic diode transistor component and second transistor component to cycle repeatedly though the states described therein;
wherein the method comprises activating the intermediate state of the second transistor component substantially at or before the end of the energising period;
wherein the method comprises controlling the second transistor component such that in the intermediate state, the second transistor component conveys more charge to or from the switching node, than that respectively conveyed from or to it jointly by the inductive component and intrinsic diode component.

31. A control circuit of the voltage converter device of claim 29, adapted to control the first and second transistor components of that voltage converter device in accordance with the method of claim 30.

32. The control circuit according to claim 31, comprising a gate driver for driving the intrinsic transistor component, and at least two gate drivers for respectively driving the at least two transistors of the second transistor component.

33. The control circuit according to claim 32, comprising a first gate driver for driving the intrinsic transistor component, and a second gate driver arranged to provide at least three voltages, respectively for controlling the second transistor component to be off, in its intermediate state, or on.

34. A method of designing a voltage converter, comprising the steps of:
selecting components and arrangement thereof to provide the voltage converter device as set out in claim 1;
selecting at least one current or voltage operating region, and an electrical performance criterion;
selecting a plurality of options for the electrical resistance of the aforementioned intermediate state of the second transistor component;
evaluating which of the options provides for the highest performance in relation to the performance criterion and operating envelope; and
selecting a circuit configuration or gate voltage for the second transistor component, to achieve the electrical resistance identified as providing the highest performance.

35. The method according to claim 34 wherein:
the step of selecting at least one current or voltage operating region, and an electrical performance criterion, comprises selecting multiple current or voltage operating regions; and
the step of selecting a circuit configuration or gate voltage for the second transistor component, to achieve the electrical resistance identified as providing the highest performance, an operating map is produced, for the control circuit to use to control the voltage converter depending on the voltage or current state of the voltage converter.
